(19) United States
(12) Patent Application Publication
(10) Pub. No.: US 2016/0314844 A1
(43) Pub. Date: Oct. 27, 2016

(54) NATURAL THRESHOLD VOLTAGE COMPACTION WITH DUAL PULSE PROGRAM FOR NON-VOLATILE MEMORY

(71) Applicant: SANDISK TECHNOLOGIES INC., Plano, TX (US)

(72) Inventors: Deepanshu Dutta, Fremont, CA (US); Huai-Yuan Tseng, San Ramon, CA (US); Farookh Moogat, Fremont, CA (US)

(73) Assignee: SANDISK TECHNOLOGIES INC., Plano, TX (US)

(21) Appl. No.: 14/926,167

(22) Filed: Oct. 29, 2015

Related U.S. Application Data
(60) Provisional application No. 62/150,947, filed on Apr. 22, 2015.

(51) Int. Cl. G11C 16/10

(52) U.S. Cl. CPC G11C 16/10

(57) ABSTRACT

A control circuit, in communication with non-volatile memory cells, is configured to distinguish and classify the memory cells into the different subsets of memory cells based on programming performance. Based on the classifying, the control circuit applies different programming signals to different subsets of the memory cells being programmed to a common data state.

### CLAIM OF PRIORITY

This application claims the benefit of U.S. Provisional Application 62/150,947, filed Apr. 22, 2015, titled “Natural Threshold Voltage Compaction With Dual Pulse Program.”

### BACKGROUND

Semiconductor memory is widely used in various electronic devices such as cellular telephones, digital cameras, personal digital assistants, medical electronics, mobile computing devices, and non-mobile computing devices. Semiconductor memory may comprise non-volatile memory or volatile memory. A non-volatile memory allows information to be stored and retained even when the non-volatile memory is not connected to a source of power (e.g., a battery). Examples of non-volatile memory include flash memory (e.g., NAND-type and NOR-type flash memory) and Electrically Erasable Programmable Read-Only Memory (EEPROM).

A charge-trapping material can be used in non-volatile memory devices to store a charge which represents a data state. The charge-trapping material can be arranged vertically in a three-dimensional (3D) stacked memory structure. One example of a 3D memory structure is the Bit Cost Scalable (BiCS) architecture which comprises a stack of alternating conductive and dielectric layers. A memory hole is formed in the stack and a NAND string is then formed by filling the memory hole with materials including a charge-trapping layer to create a vertical column of memory cells. A straight NAND string extends in one memory hole. Control gates of the memory cells are provided by the conductive layers.

Some non-volatile memory devices are used to store two ranges of charges and, therefore, the memory cell can be programmed/erased between two ranges of threshold voltages that correspond to two data states: an erased state (e.g., data “1”) and a programmed state (e.g., data “0”). Such a device is referred to as a binary or two-state device.

A multi-state non-volatile memory is implemented by identifying multiple, distinct allowed ranges of threshold voltages. Each distinct range of threshold voltages corresponds to a data state assigned a predetermined value for the set of data bits. The specific relationship between the data programmed into the memory cell and the ranges of threshold voltages depends upon the data encoding scheme adopted for the memory cells. For example, U.S. Pat. No. 6,222,762 and U.S. Patent Application Publication No. 2004/0255090 both describe various data encoding schemes for multi-state flash memory cells.

A programming operation for non-volatile memory typically includes applying doses of programming and verifying the programming after each dose of programming. While multi-state non-volatile memory can store more data than binary non-volatile memory, the process for programming and verifying the programming can take longer for multi-state non-volatile memory.

### BRIEF DESCRIPTION OF THE DRAWINGS

Like-numbered elements refer to common components in the different figures.

FIG. 1 is a perspective view of a 3D stacked non-volatile memory device.

FIG. 2 is a functional block diagram of a memory device such as the 3D stacked non-volatile memory device 100 of FIG. 1.

FIG. 3A is a block diagram depicting software modules for programming one or more processors in a Controller.

FIG. 3B is a block diagram depicting software modules for programming a state machine or other processor on a memory die.

FIG. 3C is a block diagram of an individual sense block.

FIG. 4A is a block diagram of a memory structure having two planes.

FIG. 4B depicts a top view of a portion of a block of memory cells.

FIG. 4C depicts a cross sectional view of a portion of a block of memory cells.

FIG. 4D depicts a view of the select gate layers and word line layers.

FIG. 4E is a cross sectional view of a vertical column of memory cells.

FIG. 4F is a schematic of a plurality of NAND strings.

FIG. 5 is a schematic diagram of a sense amplifier.

FIG. 6 is a timing diagram that describes the behavior of certain signals depicted in the sense amplifier of FIG. 5.

FIG. 7 is a flow chart describing one embodiment of the operation of the circuit of FIG. 5.

FIGS. 8 and 9 depict threshold voltage distributions.

FIG. 10 is a flow chart describing one embodiment of a process for programming

FIG. 11 is a flow chart describing one embodiment of a process for compacting threshold voltage distributions.

FIG. 12 is a block diagram of one example set of components that can perform the process of FIG. 11.

FIG. 13 is a flow chart describing one embodiment of a process for compacting threshold voltage distributions.

FIG. 14 is a flow chart describing one embodiment of a process for compacting threshold voltage distributions.

FIG. 15A depicts a set of threshold voltage distributions.

FIG. 15B depicts a set of threshold voltage distributions.

FIG. 15C depicts a set of threshold voltage distributions.

FIG. 15D is a flow chart describing one embodiment of a process for classifying fast and slow programming memory cells.

FIG. 16A depicts a threshold voltage distribution.

FIG. 16B is a flow chart describing one embodiment of a process for classifying fast and slow programming memory cells.

FIG. 17A depicts a set of threshold voltage distributions.

FIG. 17B depicts a set of threshold voltage distributions.

FIG. 17C is a flow chart describing one embodiment of a process for classifying fast and slow programming memory cells.

FIG. 18 depicts a set of programming pulses.

FIG. 19 is a flow chart describing one embodiment of a process for compacting threshold voltage distributions.

FIG. 20 depicts a threshold voltage distribution.

FIG. 21 is a flow chart describing one embodiment of a process for compacting threshold voltage distributions.

FIG. 22 is a timing diagram describing the behavior of word line and bit line voltages.

### DETAILED DESCRIPTION

When memory cells store multiple bits of data representing multiple data states, a verification process that verifies all possible data states can take a long time. Therefore, at a given moment in time, some systems will only verify for a subset of programmed states that the memory cells could potentially be achieving. In some embodiments, the number of data states being verified at a given time depends on the width of the natural threshold distribution. which is the distribution of threshold voltages for a population of memory cells after some amount of programming but before the memory cells are locked out from programming, artificially slowed down, or artificially sped up. It is proposed to reduce the amount of time needed to verify by reducing the width of the threshold voltage distribution so that less data states need to be verified at a given time. One embodiment that is configured to reduce the width of the threshold voltage distributions includes non-volatile memory cells and a control circuit in communication with the memory cells. The control circuit is configured to apply different programming signals to different subsets of the memory cells being programmed to a common data state.

In one example implementation, the control circuit is configured distinguish and classify the memory cells into the different subsets of memory cells based on speed of programming so that the different subsets of memory cells receive different programming signals. For example, the control circuit may distinguish between fast programming memory cells and slow programming memory cells, and then apply a first set of one or more programming pulses to the fast programming memory cells and a second set of one or more programming pulses to the slow programming memory cells. The second set of programming pulses have a higher magnitude than corresponding programming pulses in the first set of programming pulses during a common iteration of the programming process.

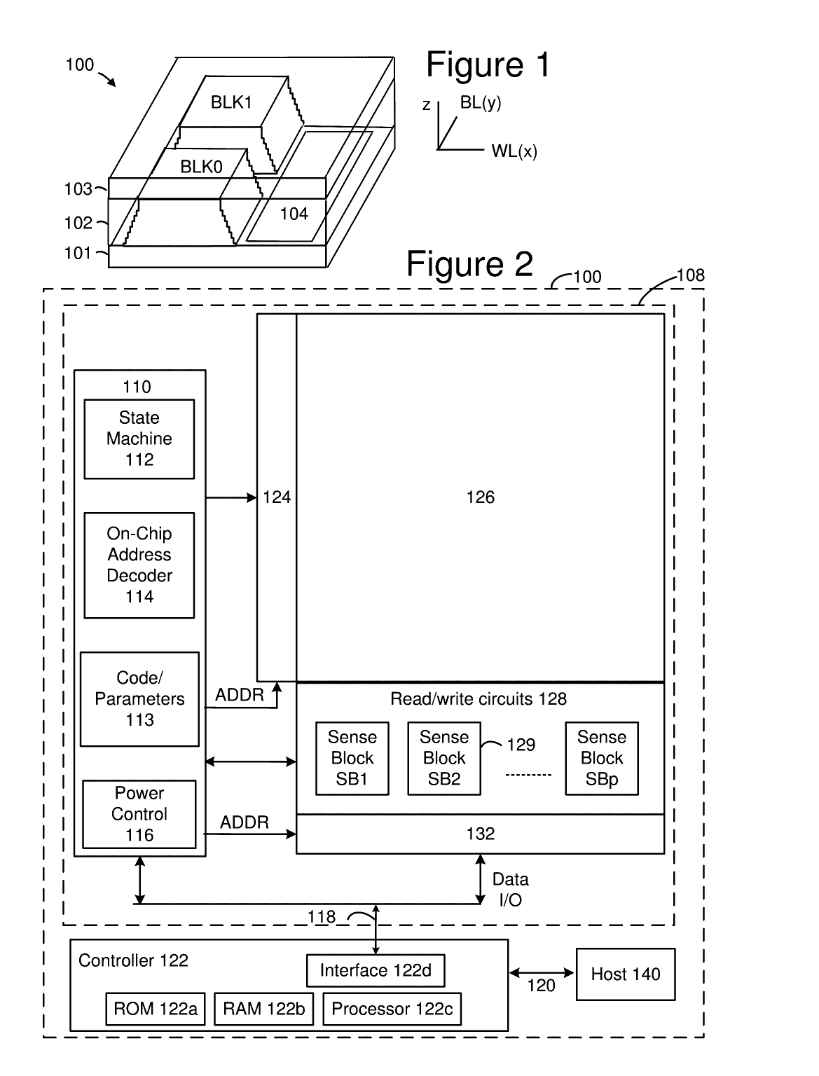

FIG. 1 is a perspective view of a three dimensional (3D) stacked non-volatile memory device that can implement the technology proposed herein. The memory device 100 includes a substrate 101. On and above the substrate are example blocks BLK0 and BLK1 of memory cells (non-volatile storage elements). Also on substrate 101 is peripheral area 104 with support circuits for use by the blocks. Substrate 101 can also carry circuits under the blocks, along with one or more lower metal layers which are patterned in conductive paths to carry signals of the circuits. The blocks are formed in an intermediate region 102 of the memory device. In an upper region 103 of the memory device, one or more upper metal layers are patterned in conductive paths to carry signals of the circuits. Each block comprises a stacked area of memory cells, where alternating levels of the stack represent word lines. While two blocks are depicted as an example, additional blocks can be used, extending in the x- and/or y-directions.

In one example implementation, the length of the plane in the x-direction, represents a direction in which signal paths for word lines extend (a word line or SGD line direction), and the width of the plane in the y-direction, represents a direction in which signal paths for bit lines extend (a bit line direction). The z-direction represents a height of the memory device.

FIG. 2 is a functional block diagram of an example memory device such as the 3D stacked non-volatile memory device 100 of FIG. 1. The components depicted in FIG. 2 are electrical circuits. Memory device 100 includes one or more memory die 108. Each memory die 108 includes a three dimensional memory structure 126 of memory cells (such as, for example, a 3D array of memory cells), control circuitry 110, and read/write circuits 128. In other embodiments, a two dimensional array of memory cells can be used. Memory structure 126 is addressable by word lines via a row decoder 124 and by bit lines via a column decoder 132. The read/write circuits 128 include multiple sense blocks SB1, SB2, . . . , SBp 129 (sensing circuitry) and allow a page of memory cells to be read or programmed in parallel.

In some systems, a controller 122 is included in the same memory device 100 (e.g., a removable storage card) as the one or more memory die 108. However, in other systems, the controller can be separated from the memory die 108. In some embodiments, one controller 122 will communicate with multiple memory die 108. In other embodiments, each memory die 108 has its own controller. Commands and data are transferred between the host 140 and controller 122 via a data bus 120, and between controller 122 and the one or more memory die 108 via lines 118. In one embodiment, memory die 108 includes a set of input and/or output (I/O) pins that connect to lines 118.

Memory structure 126 may comprise one or more arrays of memory cells including a 3D array. The memory structure may comprise a monolithic three dimensional memory structure in which multiple memory levels are formed above (and not in) a single substrate, such as a wafer, with no intervening substrates. The memory structure may comprise any type of non-volatile memory that is monolithically formed in one or more physical levels of arrays of memory cells having an active area disposed above a silicon substrate. The memory structure may be in a non-volatile memory device having circuitry associated with the operation of the memory cells, whether the associated circuitry is above or within the substrate.

Control circuitry 110 cooperates with the read/write circuits 128 to perform memory operations (e.g., erase, program, read, and others) on memory structure 126, and includes a state machine 112, an on-chip address decoder 114, and a power control module 116. The state machine 112 provides chip-level control of memory operations. Code and parameter storage 113 may be provided for storing operational parameters and software. In one embodiment, state machine 112 is programmable by the software stored in code and parameter storage 113. In other embodiments, state machine 112 does not use software and is completely implemented in hardware (e.g., electronic circuits).

The on-chip address decoder 114 provides an address interface between addresses used by host 140 or memory controller 122 to the hardware address used by the decoders 124 and 132. Power control module 116 controls the power and voltages supplied to the word lines and bit lines during memory operations. It can include drivers for word line layers (discussed below) in a 3D configuration, select transistors (e.g., SGS and SGD transistors, described below) and source lines. Power control module 116 may include charge pumps for creating voltages. The sense blocks include bit line drivers. An SGS transistor is a select gate transistor at a source end of a NAND string, and an SGD transistor is a select gate transistor at a drain end of a NAND string.

Any one or any combination of control circuitry 110, state machine 112, decoders 114/124/132, code and parameter storage 113, power control module 116, sense blocks SB1, SB2, . . . , SBp, read/write circuits 128, and controller 122 can be considered a control circuit that performs the functions described herein.

The (on-chip or off-chip) controller 122 may comprise storage devices (such as ROM 122a and RAM 122b), a processor 122c and memory interface 122d. The storage devices store code such as a set of instructions, and the processor 122c is operable to execute the set of instructions to provide the functionality described herein. Alternatively or additionally, processor 122c can access code from a storage device in the memory structure, such as a reserved area of memory cells connected to one or more word lines. Memory interface 122d, in communication with ROM 122a, RAM 122b and processor 122c, is an electrical circuit that provides an electrical interface between controller 122 and memory die 108. For example, memory interface 122d can change the format or timing of signals, provide a buffer, isolate from surges, latch I/O, etc.

Multiple memory elements in memory structure 126 may be configured so that they are connected in series or so that each element is individually accessible. By way of non-limiting example, flash memory devices in a NAND configuration (NAND flash memory) typically contain memory elements connected in series. A NAND string is an example of a set of series-connected memory cells and select gate transistors. A NAND flash memory array may be configured so that the array is composed of multiple NAND strings of which a NAND string is composed of multiple memory cells sharing a single bit line and accessed as a group. In one embodiment, NAND strings are grouped into blocks. Within a block, one end of each NAND string is connected to one of a plurality of bit lines and the other end of each NAND string is connected to a common source line for all NAND strings in the bock. Alternatively, memory elements may be configured so that each element is individually accessible, e.g., a NOR memory array. NAND and NOR memory configurations are exemplary, and memory cells may be otherwise configured.

The memory cells may be arranged in the single memory device level in an ordered array, such as in a plurality of rows and/or columns. However, the memory elements may be arrayed in non-regular or non-orthogonal configurations, or in structures not considered arrays.

A three dimensional memory array is arranged so that memory cells occupy multiple planes or multiple memory device levels, thereby forming a structure in three dimensions (i.e., in the x, y and z directions, where the z direction is substantially perpendicular and the x and y directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory cells. The vertical columns may be arranged in a two dimensional configuration, e.g., in an x-y plane, resulting in a three dimensional arrangement of memory cells, with memory cells on multiple vertically stacked memory planes. Other configurations of memory elements in three dimensions can also constitute a three dimensional memory array.

By way of non-limiting example, in a three dimensional NAND memory array, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

The technology described herein can also be utilized with technologies in addition to the charge trapping and floating gate flash memory described above. In addition to flash memory (e.g., 2D and 3D NAND-type and NOR-type flash memory), examples of non-volatile memory include ReRAM memories, magnetoresistive memory (e.g., MRAM), and phase change memory (e.g., PCRAM).

One example of a ReRAM memory includes reversible resistance-switching elements arranged in cross point arrays accessed by X lines and Y lines (e.g., word lines and bit lines). Programming can be supplied by a series of voltage pulses (ie doses of programming) on the word lines. Memory cells can be inhibited by applying a large enough voltage on the corresponding bit lines to prevent a sufficient voltage differential across the memory cell.

In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature. Applying appropriate temperatures (over discrete periods of time doses) can be used to program. Similarly, adjusting temperature can be used to inhibit. In some implementations, temperatures are controlled by applying voltages and/or currents to the memory cells and/or surrounding components.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. This configuration is known as a spin valve and is the simplest structure for an MRAM bit. A memory device is built from a grid of such memory cells. In one embodiment for programming, each memory cell lies between a pair of write lines arranged at right angles to each other, parallel to the cell, one above and one below the cell. When current is passed through them, an induced magnetic field is created (ie the dose of programming) This approach requires a fairly substantial current to generate the field. Therefore, the programming is applied as a unit of current. Sufficiently reducing or removing the current can be used to inhibit programming

Phase change memory (PCRAM) exploits the unique behavior of chalcogenide glass. One embodiment uses a GeTe-Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. Note that the use of “pulse” in this document does not require a square pulse, but includes a (continuous or non-continuous) vibration or burst of sound, current, voltage light, or other wave.

A person of ordinary skill in the art will recognize that this technology is not limited to a single specific memory structure, but covers many relevant memory structures within the spirit and scope of the technology as described herein and as understood by one of ordinary skill in the art.

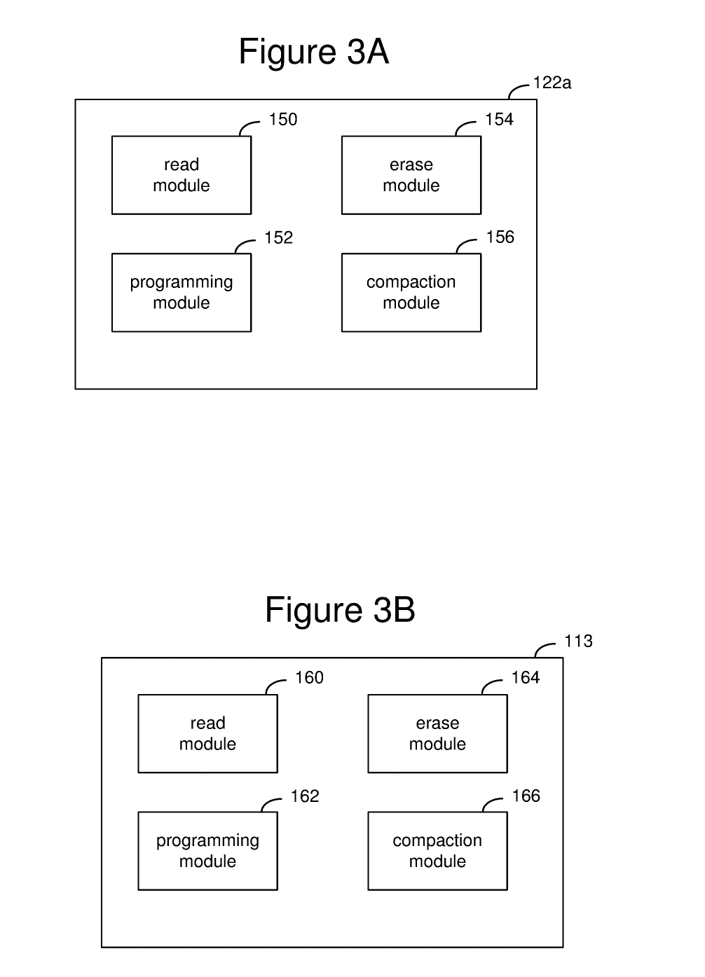

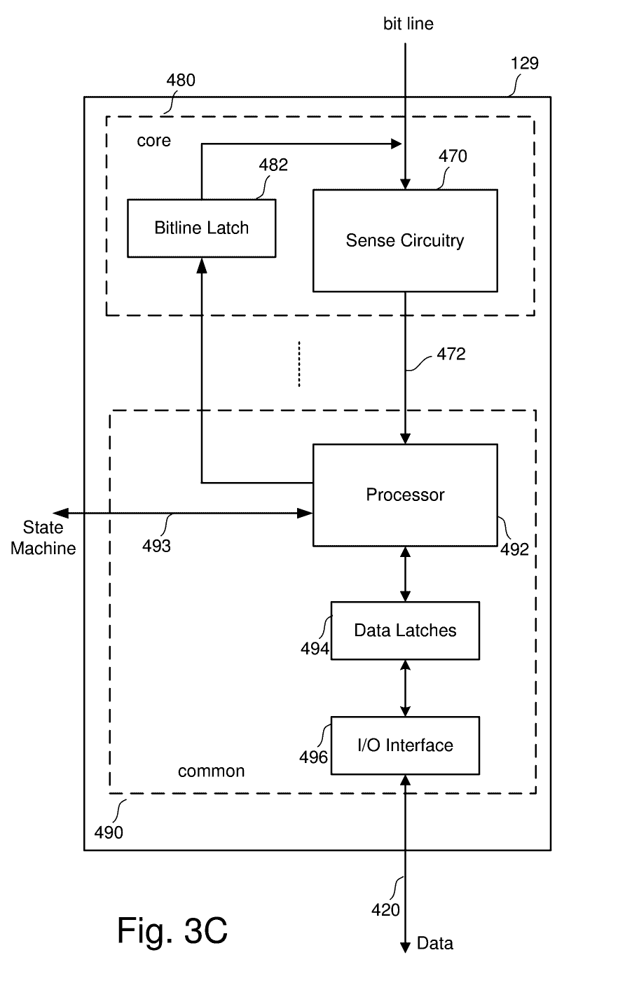

FIG. 3A is a block diagram depicting software modules for programming one or more processors in controller 122. FIG. 3A depicts read module 150, programming module 152, erase module 154 and compaction module 156 being stored in ROM 122a. These software modules can also be stored in RAM or memory die 108. Read module 150 includes software that programs processor(s) 122C to perform read operations. Programming module 152 includes software that programs processor(s) 122C to perform programming operations (including verification of programming) Erase module 154 includes software that programs processor(s) 122c to perform erase operations. Compaction module 156 includes software that programs processor(s) 122c to perform the classifying and compacting (e.g., applying different programming signals to different subsets of the memory cells being programmed to a common programmed state) described below. Based on the software, controller 122 instructs memory die 108 to perform memory operations.

FIG. 3B is a block diagram depicting software modules for programming state machine 112 (or other processor on memory die 108). FIG. 3B depicts read module 160, programming module 162, erase module 164 and compaction module 166 being stored in code and parameter storage 113. These software modules can also be stored in RAM or in memory structure 126. Read module 160 includes software that programs state machine 112 to perform read operations. Programming module 152 includes software that programs state machine 112 to perform programming operations (including verification of programming) Erase module 154 includes software that programs state machine 112 to perform erase operations. Compaction module 166 includes software that programs state machine 112 to perform the classifying and compacting (e.g., applying different programming signals to different subsets of the memory cells being programmed to a common programmed state) described below. Alternatively, state machine 112 (which is an electronic circuit) can be completely implemented with hardware so that no software is needed to perform these functions.

FIG. 3C is a block diagram of an individual sense block 129 partitioned into a core portion, referred to as a sense module 480, and a common portion 490. In one embodiment, there will be a separate sense module 480 for each bit line and one common portion 490 for a set of multiple sense modules 480. In one example, a sense block will include one common portion 490 and eight sense modules 480. Each of the sense modules in a group will communicate with the associated common portion via a data bus 472.

Sense module 480 comprises sense circuitry 470 that determines whether a conduction current in a connected bit line is above or below a predetermined level. In some embodiments, sense module 480 includes a circuit commonly referred to as a sense amplifier. Sense module 480 also includes a bit line latch 482 that is used to set a voltage condition on the connected bit line. For example, a predetermined state latched in bit line latch 482 will result in the connected bit line being pulled to a state designating program inhibit (e.g., Vdd).

Common portion 490 comprises a processor 492, a set of data latches 494 and an I/O Interface 496 coupled between the set of data latches 494 and data bus 420. Processor 492 performs computations. For example, one of its functions is to determine the data stored in the sensed memory cell and store the determined data in the set of data latches. The set of data latches 494 is used to store data bits determined by processor 492 during a read operation. It is also used to store data bits imported from the data bus 420 during a program operation. The imported data bits represent write data meant to be programmed into the memory. I/O interface 496 provides an interface between data latches 494 and the data bus 420.

During read or sensing, the operation of the system is under the control of state machine 112 that controls the supply of different voltages to the addressed memory cell. As it steps through the various predefined voltages (the read reference voltages or the verify reference voltages) corresponding to the various memory states supported by the memory, the sense module 480 may trip at one of these voltages and an output will be provided from sense module 480 to processor 492 via bus 472. At that point, processor 492 determines the resultant memory state by consideration of the tripping event(s) of the sense module and the information about the applied control gate voltage from the state machine via input lines 493. It then computes a binary encoding for the memory state and stores the resultant data bits into data latches 494. In another embodiment of the core portion, bit line latch 482 serves double duty, both as a latch for latching the output of the sense module 480 and also as a bit line latch as described above.

It is anticipated that some implementations will include multiple processors 492. In one embodiment, each processor 492 will include an output line (not depicted in FIG. 3C) such that each of the output lines is wired-OR'd together. In some embodiments, the output lines are inverted prior to being connected to the wired-OR line. This configuration enables a quick determination during the program verification process of when the programming process has completed because the state machine receiving the wired-OR line can determine when all bits being programmed have reached the desired level. For example, when each bit has reached its desired level, a logic zero for that bit will be sent to the wired-OR line (or a data one is inverted). When all bits output a data 0 (or a data one inverted), then the state machine knows to terminate the programming process. In embodiments where each processor communicates with eight sense modules, the state machine may (in some embodiments) need to read the wired-OR line eight times, or logic is added to processor 492 to accumulate the results of the associated bit lines such that the state machine need only read the wired-OR line one time. In some embodiments that have many sense modules, the wired-OR lines of the many sense modules can be grouped in sets of N sense modules, and the groups can then be grouped to form a binary tree.

During program or verify, the data to be programmed is stored in the set of data latches 494 from the data bus 420. The program operation, under the control of the state machine, comprises a series of programming voltage pulses (with increasing magnitudes) concurrently applied to the addressed memory cells to that the memory cells are programmed at the same time. Each programming pulse is followed by a verify process to determine if the memory cell has been programmed to the desired state. Processor 492 monitors the verified memory state relative to the desired memory state. When the two are in agreement, processor 492 sets the bit line latch 482 so as to cause the bit line to be pulled to a state designating program inhibit. This inhibits the memory cell coupled to the bit line from further programming even if it is subjected to programming pulses on its control gate. In other embodiments the processor initially loads the bit line latch 482 and the sense circuitry sets it to an inhibit value during the verify process.

Data latch stack 494 contains a stack of data latches corresponding to the sense module. In one embodiment, there are three (or four or another number) data latches per sense module 480. In some implementations (but not required), the data latches are implemented as a shift register so that the parallel data stored therein is converted to serial data for data bus 420, and vice versa. In one preferred embodiment, all the data latches corresponding to the read/write block of memory cells can be linked together to form a block shift register so that a block of data can be input or output by serial transfer. In particular, the bank of read/write modules is adapted so that each of its set of data latches will shift data into or out of the data bus in sequence as if they are part of a shift register for the entire read/write block.

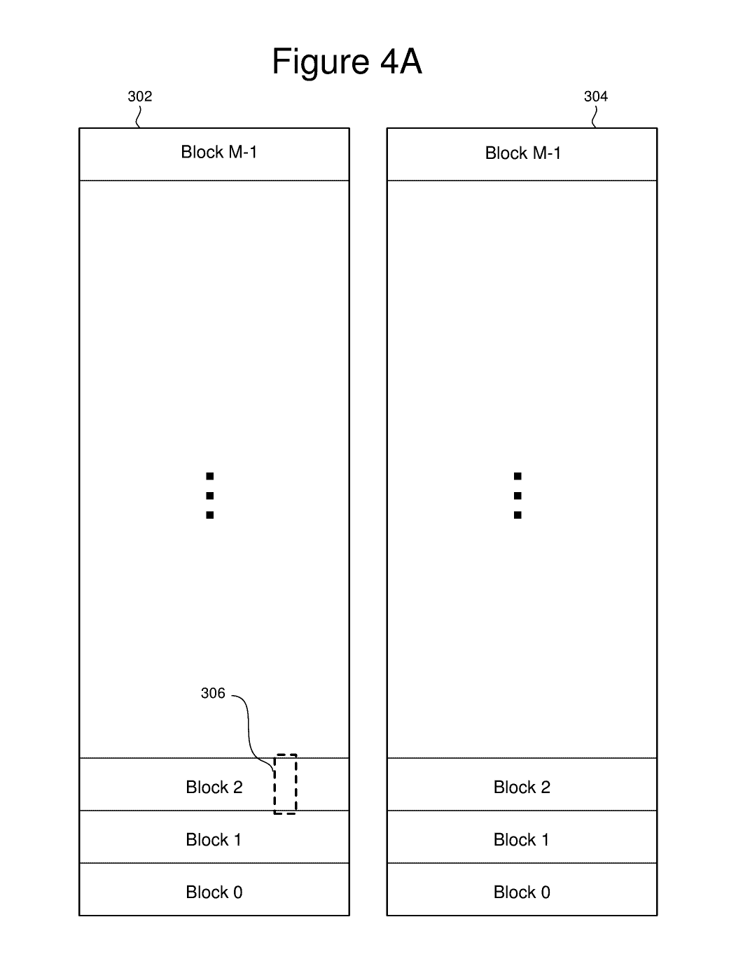

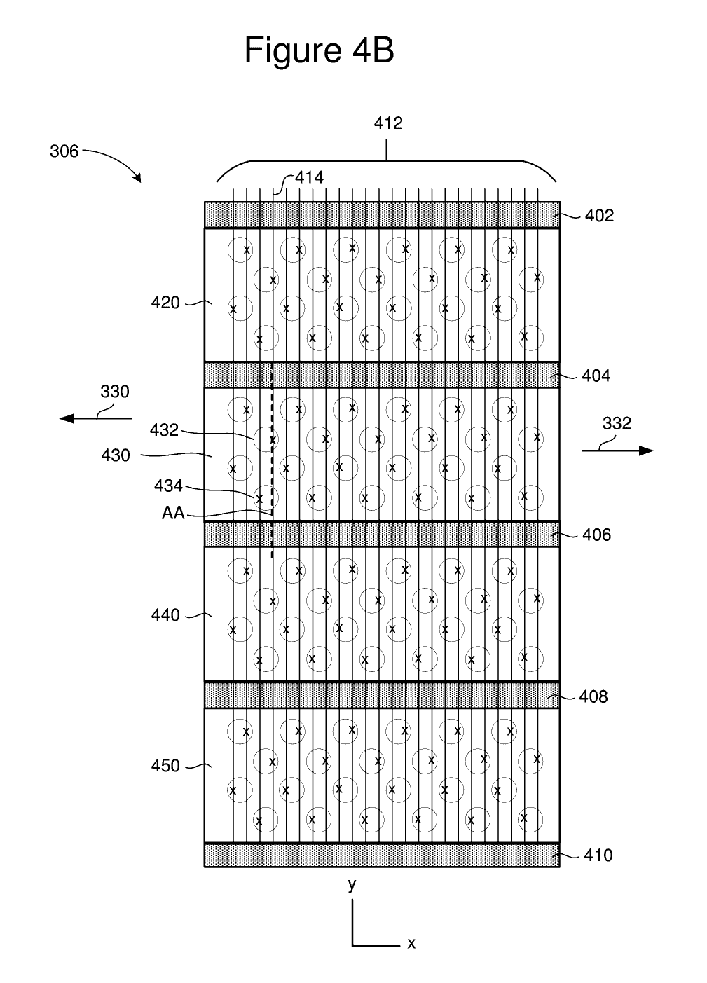

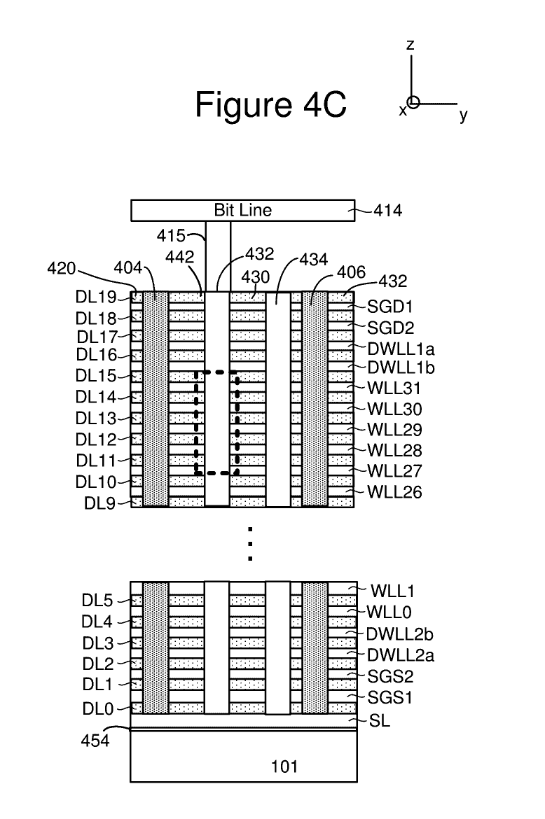

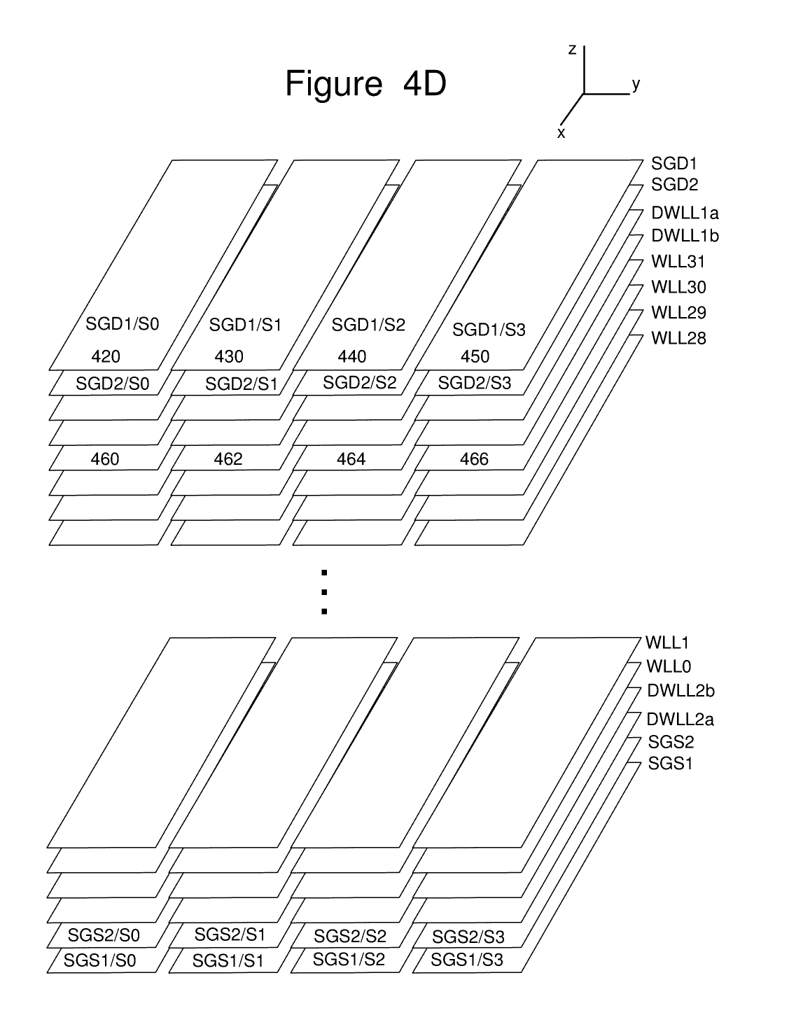

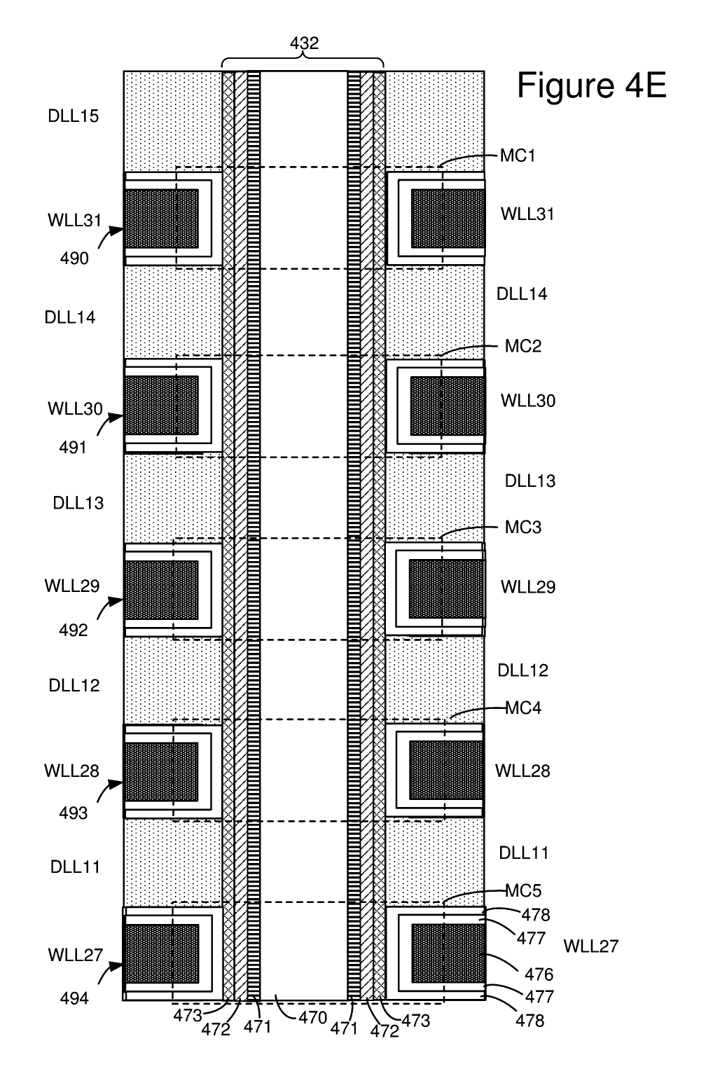

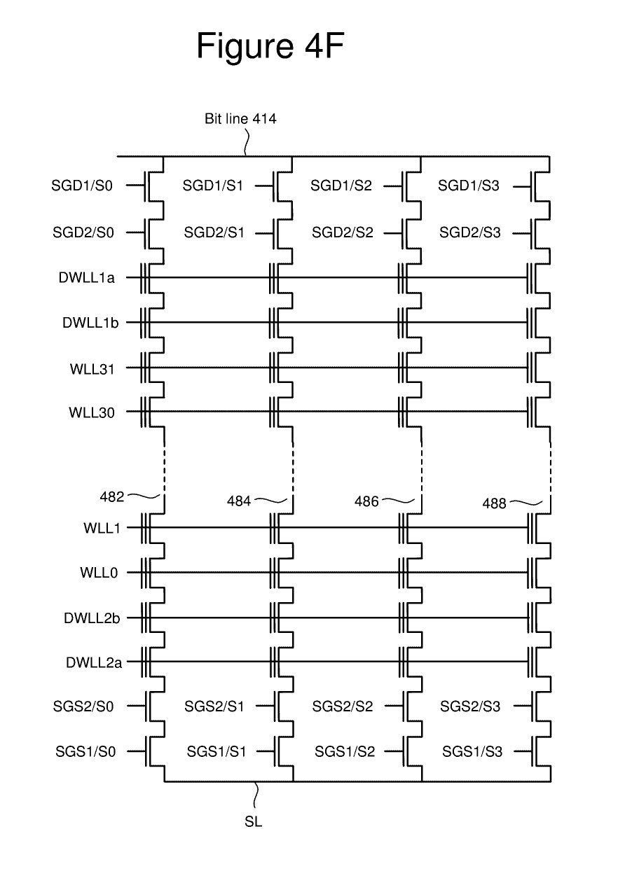

FIG. 4A is a block diagram explaining one example organization of memory structure 126, which is divided into two planes 302 and 304. Each plane is then divided into M blocks. In one example, each plane has about 2000 blocks. However, different numbers of blocks and planes can also be used.

FIGS. 4B-4E depict an example 3D NAND structure. FIG. 4B is a block diagram depicting a top view of a portion of one block from memory structure 126. The portion of the block depicted in FIG. 4B corresponds to portion 306 in block 2 of FIG. 4A. As can be seen from FIG. 4B, the block depicted in FIG. 4B extends in the direction of arrow 330 and in the direction of arrow 332. In one embodiment, the memory array will have 48 layers. Other embodiments have less than or more than 48 layers. However, FIG. 4B only shows the top layer.

FIG. 4B depicts a plurality of circles that represent the vertical columns Each of the vertical columns include multiple select transistors and multiple memory cells. In one embodiment, each vertical column implements a NAND string. More details of the vertical columns are provided below. Since the block depicted in FIG. 4B extends in the direction of arrow 330 and in the direction of arrow 332, the block includes more vertical columns than depicted in FIG. 4B

FIG. 4B also depicts a set of bit lines 412. FIG. 4B shows twenty four bit lines because only a portion of the block is depicted. It is contemplated that more than twenty four bit lines connected to vertical columns of the block. Each of the circles representing vertical columns has an “x” to indicate its connection to one bit line.

The block depicted in FIG. 4B includes a set of local interconnects 402, 404, 406, 408 and 410 that connect the various layers to a source line below the vertical columns Local interconnects 402, 404, 406, 408 and 410 also serve to divide each layer of the block into four regions; for example, the top layer depicted in FIG. 4B is divided into regions 420, 430, 440 and 450. In the layers of the block that implement memory cells, the four regions are referred to as word line fingers that are separated by the local interconnects. In one embodiment, the word line fingers on a common level of a block connect together at the end of the block to form a single word line. In another embodiment, the word line fingers on the same level are not connected together. In one example implementation, a bit line only connects to one vertical column in each of regions 420, 430, 440 and 450. In that implementation, each block has sixteen rows of active columns and each bit line connects to four rows in each block. In one embodiment, all of four rows connected to a common bit line are connected to the same word line (via different word line fingers on the same level that are connected together); therefore, the system uses the source side select lines and the drain side select lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts a portion of an embodiment of three dimensional memory structure 126 showing a cross-sectional view along line AA of FIG. 4B. This cross sectional view cuts through vertical columns 432 and 434 and region 430 (see FIG. 4B). The structure of FIG. 4C includes two drain side select layers SGD1 and SGD1; two source side select layers SGS1 and SGS2; four dummy word line layers DWLL1a, DWLL1b, DWLL2a and DWLL2b; and thirty two word line layers WLL0-WLL31 for connecting to data memory cells. Other embodiments can implement more or less than two drain side select layers, more or less than two source side select layers, more or less than four dummy word line layers, and more or less than thirty two word line layers. Vertical columns 432 and 434 are depicted protruding through the drain side select layers, source side select layers, dummy word line layers and word line layers. In one embodiment, each vertical column comprises a NAND string. Below the vertical columns and the layers listed below is substrate 101, an insulating film 454 on the substrate, and source line SL. The NAND string of vertical column 432 has a source end at a bottom of the stack and a drain end at a top of the stack. As in agreement with FIG. 4B, FIG. 4C show vertical column 432 connected to Bit Line 414 via connector 415. Local interconnects 404 and 406 are also depicted.

For ease of reference, drain side select layers SGD1 and SGD1; source side select layers SGS1 and SGS2; dummy word line layers DWLL1a, DWLL1b, DWLL2a and DWLL2b; and word line layers WLL0-WLL31 collectively are referred to as the conductive layers. In one embodiment, the conductive layers are made from a combination of TiN and Tungsten. In other embodiments, other materials can be used to form the conductive layers, such as doped polysilicon, metal such as Tungsten or metal silicide. In some embodiments, different conductive layers can be formed from different materials. Between conductive layers are dielectric layers DL0-DL19. For example, dielectric layers DL10 is above word line layer WLL26 and below word line layer WLL27. In one embodiment, the dielectric layers are made from SiO₂. In other embodiments, other dielectric materials can be used to form the dielectric layers.

The memory cells are formed along vertical columns which extend through alternating conductive and dielectric layers in the stack. In one embodiment, the memory cells are arranged in NAND strings. The word line layer WLL0-WLL31 connect to memory cells (also called data memory cells). Dummy word line layers DWLL1a, DWLL1b, DWLL2a and DWLL2b connect to dummy memory cells. A dummy memory cell, also referred to as a non-data memory cell, does not store user data, while a data memory cell is eligible to store user data. Thus, data memory cells may be programmed. Drain side select layers SGD1 and SGD1 are used to electrically connect and disconnect NAND strings from bit lines. Source side select layers SGS1 and SGS2 are used to electrically connect and disconnect NAND strings from the source line SL.

FIG. 4D depicts a perspective view of the conductive layers (SGD1, SGD2, SGS1, SGS2; DWLL1a, DWLL1b, DWLL2a, DWLL2b, and WLL0-WLL31) for the block that is partially depicted in FIG. 4C. As mentioned above with respect to FIG. 4B, local interconnects 401, 404, 406, 408 and 410 break up each conductive layers into four regions. For example, drain side select gate layer SGD1 (the top layer) is divided into regions 420, 430, 440 and 450. Similarly, word line layer WLL31 is divided into regions 460, 462, 464 and 466. For word line layers (WLL0-WLL31), the regions are referred to as word line fingers; for example, word line layer WLL31 is divided into word line fingers 460, 462, 464 and 466. In one embodiment, each word line finger operates as a separate word line. In another embodiment, the four word line fingers on a same level are connected together.

Drain side select gate layer SGD1 (the top layer) is also divided into regions 420, 430, 440 and 450, also known as fingers or select line fingers. In one embodiment, each of the select line finger operates as a separate word line; therefore, region 420 is labeled as select line SGD1/S0 (ie select line 0 of drain side select line layer 0), region 430 is labeled as select line SGD1/S1 (ie select line 1 of drain side select line layer 0), region 440 is labeled as select line SGD1/S2, and region 450 is labeled as select line SGD1/S3. Similarly, drain side select gate layer SGD2 has four fingers that operate as select lines SGD2/S0, SGD2/S1, SGD2/S2, and SGD2/S3. Source side select gate layer SGS1 has four fingers that operate as select lines SGS1/S0, SGS1/S1, SGS1/S2, and SGS1/S3. Source side select gate layer SGS2 has four fingers that operate as select lines SGS2/S0, SGS2/S1, SGS2/S2, and SGS2/S3.

FIG. 4E depicts a cross sectional view of region 442 of FIG. 4C that includes a portion of vertical column 432. In one embodiment, the vertical columns are round and include four layers; however, in other embodiments more or less than four layers can be included and other shapes can be used. In one embodiment, vertical column 432 includes an inner core layer 470 that is made of a dielectric, such as SiO₂. Other materials can also be used. Surrounding inner core 470 is polysilicon channel 471. Materials other than polysilicon can also be used. Note that it is the channel 471 that connects to the bit line. Surrounding channel 471 is a tunneling dielectric 472. In one embodiment, tunneling dielectric 472 has an ONO structure. Surrounding tunneling dielectric 472 is charge trapping layer 473, such as (for example) a specially formulated silicon nitride that increases trap density.

FIG. 4E depicts dielectric layers DLL11, DLL12, DLL13, DLL14 and DLL15, as well as word line layers WLL27, WLL28, WLL29, WLL30, and WLL31. Each of the word line layers includes a word line region 476 surrounded by an aluminum oxide layer 477, which is surrounded by a blocking oxide (SiO₂) layer 478. The physical interaction of the word line layers with the vertical column forms the memory cells. Thus, a memory cell, in one embodiment, comprises channel 471, tunneling dielectric 472, charge trapping layer 473, blocking oxide layer 478, aluminum oxide layer 477 and word line region 476. For example, word line layer WLL31 and a portion of vertical column 432 comprise a memory cell MC1. Word line layer WLL30 and a portion of vertical column 432 comprise a memory cell MC2. Word line layer WLL29 and a portion of vertical column 432 comprise a memory cell MC3. Word line layer WLL28 and a portion of vertical column 432 comprise a memory cell MC4. Word line layer WLL27 and a portion of vertical column 432 comprise a memory cell MC5. In other architectures, a memory cell may have a different structure; however, the memory cell would still be the storage unit.

When a memory cell is programmed, electrons are stored in a portion of the charge trapping layer 473 which is associated with the memory cell. These electrons are drawn into the charge trapping layer 473 from the channel 471, through the tunneling layer 473, in response to an appropriate voltage on word line region 476. The threshold voltage (Vth) of a memory cell is increased in proportion to the amount of stored charge. During an erase operation, the electrons return to the channel or holes recombine with electrons.

FIG. 4F is a circuit diagram depicting a plurality of groups of connected programmable and erasable non-volatile memory cells arranged as four NAND strings connected to bit line 414 and common source line SL. The select lines SGD1/S0, SGD1/S1, SGD1/S2, SGD1/S3, SGD2/S0, SGD2/S1, SGD2/S2, SGD2/S3, SGS1/S0, SGS1/S1, SGS1/S2, SGS1/S3, SGS2/S0, SGS2/S1, SGS2/S2, and SGS2/S3 are used to select/unselect the depicted NAND strings. In one embodiment, there are two select lines (and, therefore, two select gates) on each side of each NAND string. Other embodiments can use more than two select lines (and two select gates) on each side or less than two select lines (and two select gates) on each side of the NAND strings. In the embodiment depicted in FIG. 4F, to connect a NAND string to the bit line both select gates must be actuated (via the two respective select lines) and to connect a NAND string to the common source line SL both select gates must be actuated (via the two respective select lines).

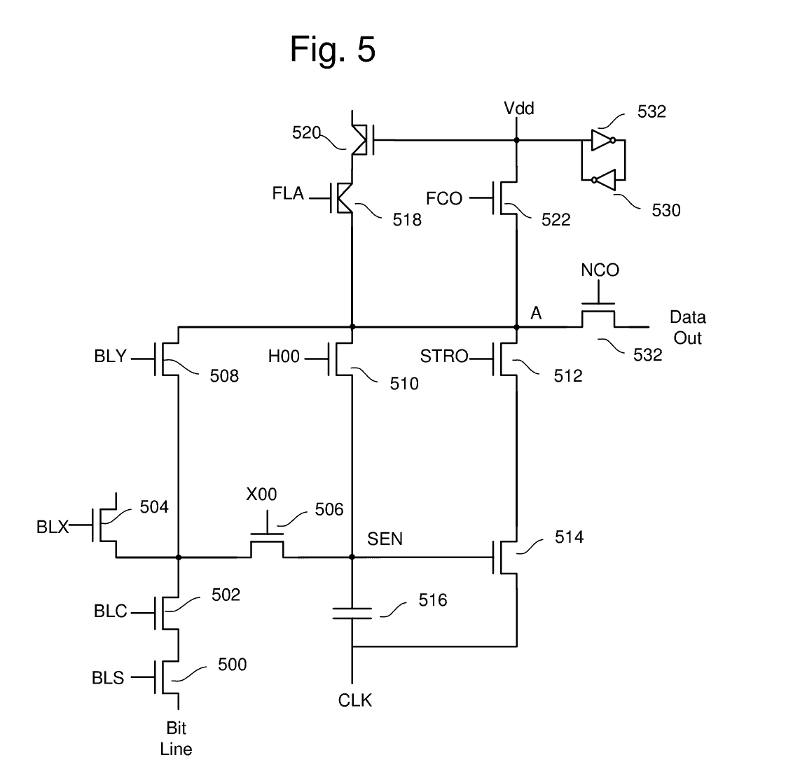

FIG. 5 is a schematic diagram depicting a sense amplifier circuit. Each sense block SB1, SB2, SBp (see FIG. 2) would include multiple sense amplifier circuits (e.g., sense circuitry 470). As described below, the circuit of FIG. 5 will pre-charge a capacitor (or other charge storage device) to a pre-charge magnitude, discharge the capacitor through the memory cell for a strobe time, and sense voltage at the capacitor after the strobe time. The sense voltage will be indicative of whether the memory cells conducted the current being sensed for, which is indicative of whether the threshold voltage of the memory cell is greater than or less than threshold voltage being tested for (corresponding to the control gate voltage). If the threshold voltage of the memory cell is greater than the threshold voltage being tested, then, during a verify operation, the memory cell will complete programming, as appropriate based on the processes described herein. FIG. 5 shows transistor 500 connected to the Bit Line and transistor 502. Transistor 500 receives the signal BLS at its gate, and is used to connect to or isolate the Bit Line. Transistor 502 receives the signal BLC at its gate, and is used as a voltage clamp. The gate voltage BLC is biased at a constant voltage equal to the desired Bit Line voltage plus the threshold voltage of transistor 502. The function of transistor 502, therefore, is to maintain a constant Bit Line voltage during a sensing operation (during read or verify), even if the current through the Bit Line changes.

Transistor 502 is connected to transistors 504, 506 and 508. Transistor 506 is connected to capacitor 516 at the node marked SEN. The purpose of transistor 506 is to connect capacitor 516 to Bit Line 500 and disconnect capacitor 516 from Bit Line 500 so that capacitor 516 is in selective communication with Bit Line 500. In other words, transistor 506 regulates the strobe time. That is, while transistor 506 is turned on capacitor 516 can discharge through the Bit Line, and when transistor 506 is turned off capacitor 516 cannot discharge through the Bit Line.

The node at which transistor 506 connects to capacitor 516 is also connected to transistor 510 and transistor 514. Transistor 510 is connected to transistors 508, 512 and 518. Transistor 518 is also connected to transistor 520. Transistors 518 and 520 are PMOS transistors while the other transistors of FIG. 5 are NMOS transistors. Transistors 510, 518, and 520 provide a pre-charging path to capacitor 516. A voltage (e.g. Vdd or other voltage) is applied to the source of transistor 520. By appropriately biasing transistors 510, 518 and 520, the voltage applied to the source of transistor 520 can be used to pre-charge capacitor 516. After pre-charging, capacitor 516 can discharge through the Bit Line via transistor 506 (assuming that transistors 500 and 502 are conducting).

The circuit of FIG. 5 includes inverters 530 and 532 forming a latch circuit. The output of inverter 532 is connected to the input of inverter 530 and the output of inverter 530 is connected to the input of inverter 532 as well as transistors 520 and 522. The input of inverter 532 will receive Vdd and the two inverters 530, 532 will act as a latch to store Vdd. The input of inverter 532 can also be connected to another value. Transistors 512 and 522 provide a path for communicating the data stored by inverters 530 and 532 to transistor 514. Transistor 522 receives the signal FCO at its gate. Transistor 512 receives the signal STRO at its gate. By raising or lowering FCO and STRO, a path is provided or cut off between the inverters 530, 532 and transistor (sensing switch) 514. The gate of transistor 514 is connected capacitor 516, transistor 506 and transistor 510 at the node marked SEN. The other end of capacitor 516 is connected to the signal CLK.

As discussed above, capacitor 516 is pre-charged via transistors 510, 518 and 520. This will raise the voltage at the SEN node to a pre-charge voltage level (Vpre). When transistor 506 turns on, capacitor 516 can discharge its charge through the Bit Line and the selected memory cell if the threshold voltage of the memory cell is below the voltage level being tested for. If the capacitor 516 is able to discharge, then the voltage at the capacitor (at the SEN node) will decrease.

The pre-charge voltage (Vpre) at the SEN node is greater than the threshold voltage of transistor 914; therefore, prior to the strobe time, transistor 514 is on (conducting). Since transistor 514 is on during the strobe time, then transistor 512 should be off. If the capacitor does not discharge during the strobe time, then the voltage at the SEN node will remain above the threshold voltage of transistor 514 and the charge at the inverters 530, 532 can be discharged into the CLK signal when STRO turns on transistor 512. If the capacitor discharges sufficiently during the strobe time, then the voltage at the SEN node will decrease below the threshold voltage of transistor 514; thereby, turning off transistor 914 and the data (e.g., Vdd) stored at inverters 530, 532 from being discharged through CLK. So testing whether the diodes 530, 532 maintain their charge or discharge will indicate the result of the verification process. In one embodiment, the result can be read at node A via transistor 534 (Data Out) by turning on transistor 534 gate signal NCO.

The pre-charge level of capacitor 516 (and, thus, the pre-charge voltage at node SEN) is limited by the current passing through transistor 510. The current that passes through transistor 510 is limited by the gate voltage H00. As such, the pre-charge voltage at node SEN is limited by the voltage H00 less the threshold voltage of transistor 510. With this arrangement, the system can regulate the pre-charge voltage at node SEN by regulating H00. A larger voltage at H00 results in a larger voltage at the SEN node when pre-charging. A lower voltage at H00 results in a lower voltage at the SEN node when pre-charging.

When the system performs a read or verify operation (both are sense operations), the voltage applied to the control gate of the cell may cause the channel (connected to the bit line) of the cell to conduct. If this happens, a capacitor is discharged through the channel, lowering in voltage as it discharges.

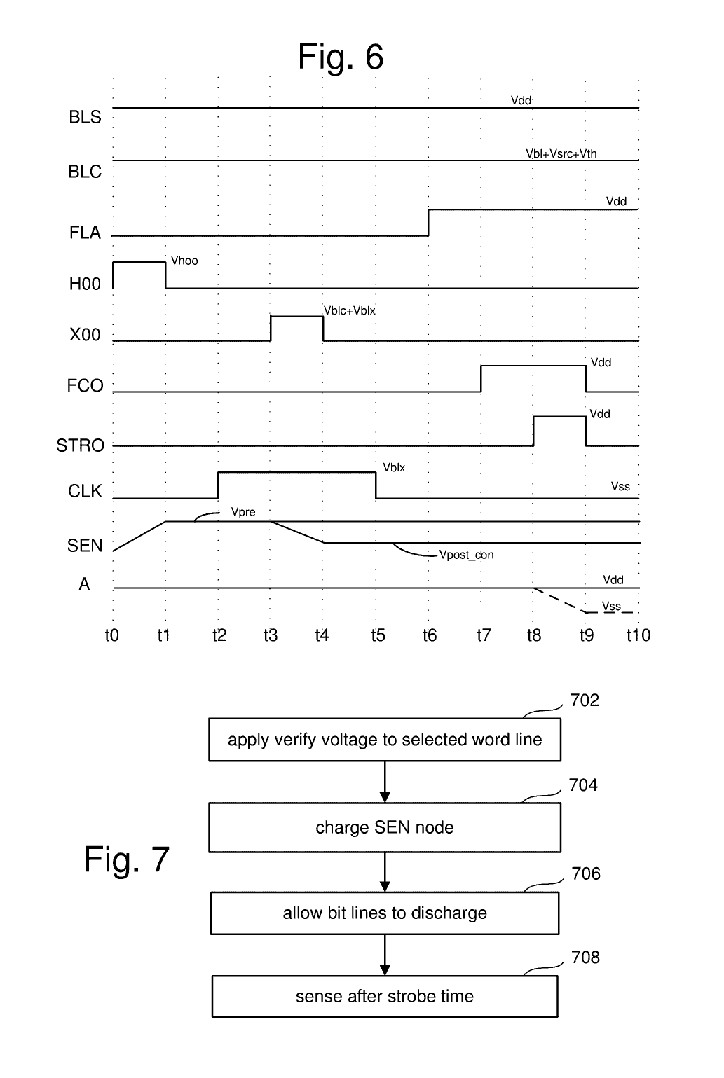

FIG. 6 is a timing diagram describing the behavior of various signals from FIG. 5. The signal BLS is at Vdd the entire time depicted and the signal BLC is at Vb1+Vsrc+Vth, where Vb1 is the voltage of the Bit Line, Vsrc is the voltage of the source line and Vth is the threshold voltage of transistor 502. The signal FLA starts at Vss at t0 and goes to Vdd at t6. When the signal FLA is at Vss, the pre-charging path is regulated by transistor 510. At t0, the voltage of H00 is raised from ground to a pre-charge level. The raising of the voltage at H00 turns on transistor 510 and opens up the pre-charge path. The magnitude of the voltage at H00 is set. FIG. 6 shows H00 going to Vhoo. The signal H00 will stay at the pre-charge voltage (Vhoo) until time t1. While H00 is high, transistor 510 turns on and capacitor 516 will pre-charge between t0 and t1, as depicted by the voltage at SEN. At time t1, H00 is brought down to Vss and the pre-charging is completed.

The signal X00 is used to allow capacitor 516 to be in communication with the Bit Line so that the capacitor can discharge through the Bit Line and selected memory cell. At time t3, X00 is raised to Vb1c+Vb1x, where Vb1c is the voltage of the signal BLC and Vb1x is the voltage of the signal BLX (both discussed above). At time t4, the voltage at X00 is lowered to Vss. Between times t3 and t4, known as the strobe time, capacitor 516 will be in communication with the Bit Line in order to allow it to discharge through the Bit Line and the selected memory cell (depending on the threshold voltage of the selected memory cell). The signal CLK is raised to Vb1x at time t2 and lowered back down to Vss at time t5 to prevent any fighting conditions in the circuit and to allow proper discharge of capacitor 516.

As discussed above, because H00 is raised between t0 and t1, capacitor 516 (and SEN node) will charge up between t0 and t1 (the pre-charge). This is depicted in FIG. 6 with the SEN node charging from Vss to Vpre. The solid line for Vpre represents an example pre-charging of the node SEN (and capacitor 516) in response to Vh00 being applied to the gate of transistor 510.

When X00 is raised up at t3, capacitor 516 can initially pre-charge the bit line and then discharge through the Bit Line (if the threshold voltage is at the appropriate level). As depicted in FIG. 6 between t3 and t4, the voltage at the SEN node can will dissipate from Vpre to Vpost_con if the memory cell turns on (conducts) because its threshold voltage is less than or equal to the voltage being applied to its control gate. If the threshold voltage for the memory cell being tested is higher than the voltage applied to its control gate, capacitor 516 will not discharge and the voltage will remain at Vpre. The period between t3 and t4 is the strobe time and can be adjusted, as described above.

FIG. 6 shows that the signal FCO is raised to Vdd at t7 and lowered to Vss at T9. The signal STRO is raised to Vdd at t8 and lowered at t9. Between times t8 and t9, there is a path between the inverters 530, 532 and transistor 514. If the voltage at the node SEN is greater than the threshold voltage of transistor 514, then there will be a path from the inverters 530, 532 to CLK and the data at the inverters 530, 532 will dissipate through the signal CLK and through the transistor 514. If the voltage at the node SEN is lower than threshold voltage of transistor 514 (e.g. if the capacitor discharged), then transistor 514 will turn off and the voltage stored by the inverters 530, 532 will not dissipate into CLK. FIG. 6 shows the voltage level at node A at Vdd. If the voltage of the capacitor does not dissipate (e.g., due to not enough current flowing because the threshold voltage of the selected memory cell is greater than the voltage being tested for), then transistor 514 will remain on and the voltage at node A will dissipate to Vss (as depicted by the dashed line). If the voltage of the capacitor does dissipate (e.g., due to sufficient current flowing because the threshold voltage of the selected memory cell is below the voltage being tested for), then transistor 514 will turn off and the voltage at node A will remain at Vdd (as depicted by the solid line). The output of node A is provided to the Data Out signal via transistor 534 by applying Vdd to the signal NCO.

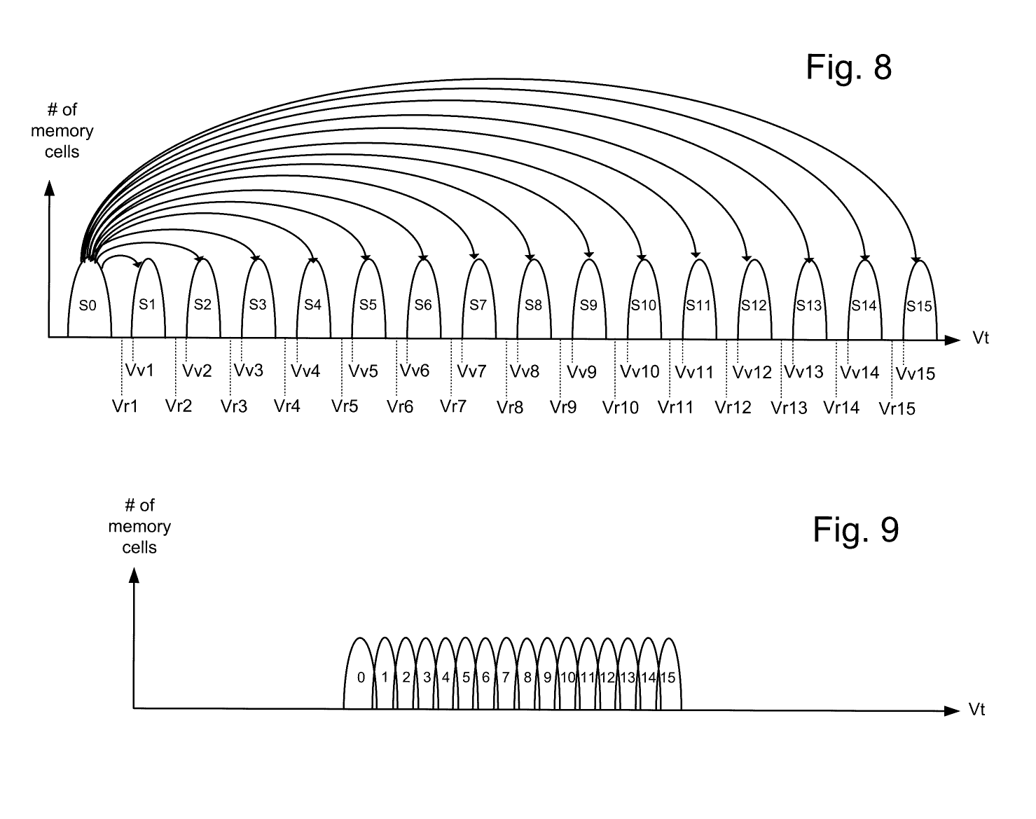

FIG. 7 is a flow chart describing a sensing operation performed according to the timing diagram of FIG. 6. In step 702, the appropriate verify reference voltage (e.g., Vv, Vv1, Vv2, Vv3, Vv4, Vv5, Vv6, or Vv7—see FIG. 8) is applied is applied to the selected word line. The selected word line is connected to the memory cells being programmed and verified. The bit lines connected to the memory cells being programmed and verified are charged to a pre-determined pre-charge level. In step 704, all of the SEN nodes are pre-charged. In step 706, the bit lines are allowed to discharge, for example, by discharging the capacitor 516 (see t5-t6 of FIG. 6). After a predetermined time period, referred to as the “strobe time” or “integration time” the voltage of the capacitor 516 (or the SEN node) is sampled as described above to see whether the respective memory cell(s) conducted in step 708. As described above, the verification process is performed simultaneously for thousands of memory cells connected to the same word line and different bit lines.

At the end of a successful programming process (with verification), the threshold voltages of the memory cells should be within one or more distributions of threshold voltages for programmed memory cells or within a distribution of threshold voltages for erased memory cells, as appropriate. FIG. 8 illustrates example threshold voltage distributions for the memory cell array when each memory cell stores four bits of data. Other embodiments, however, may use other data capacities per memory cell (e.g., such as one, two, three, or five bits of data per memory cell). FIG. 8 shows sixteen threshold voltage distributions, corresponding to sixteen data states. The first threshold voltage distribution (data state) S0 represents memory cells that are erased. The other fifteen threshold voltage distributions (data states) S1-S15 represent memory cells that are programmed and, therefore, are also called programmed states. Each threshold voltage distribution (data state) corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a floating gate erroneously shifts to its neighboring physical state, only one bit will be affected. Note that state N-1 is an adjacent lower data state for state N; for example, state 7 is an adjacent lower data state for state 8.

FIG. 8 also shows fifteen read reference voltages, Vr1, Vr2, Vr3, Vr4, Vr5, Vr6, Vr7, Vr8, Vr9, Vr10, Vr11, Vr12, Vr13, Vr14 and Vr15, for reading data from memory cells. By testing whether the threshold voltage of a given memory cell is above or below the fifteen read reference voltages, the system can determine what data state (i.e., S0, S1, S2, S3, . . . ) the memory cell is in.

FIG. 8 also shows fifteen verify reference voltages, Vv1, Vv2, Vv3, Vv4, Vv5, Vv6, Vv7, Vv8, Vv9, Vv10, Vv11, Vv12, Vv13, Vv14 and Vv15. When programming memory cells to data state S1, the system will test whether those memory cells have a threshold voltage greater than or equal to Vv1. When programming memory cells to data state S2, the system will test whether the memory cells have threshold voltages greater than or equal to Vv2. When programming memory cells to data state S3, the system will determine whether memory cells have their threshold voltage greater than or equal to Vv3. When programming memory cells to data state S4, the system will test whether those memory cells have a threshold voltage greater than or equal to Vv4. When programming memory cells to data state S5, the system will test whether those memory cells have a threshold voltage greater than or equal to Vv4. When programming memory cells to data state S6, the system will test whether those memory cells have a threshold voltage greater than or equal to Vv6. When programming memory cells to data state S7, the system will test whether those memory cells have a threshold voltage greater than or equal to Vv7. When programming memory cells to data state S8, the system will test whether those memory cells have a threshold voltage greater than or equal to Vv8. When programming memory cells to data state S9, the system will test whether those memory cells have a threshold voltage greater than or equal to Vv9. When programming memory cells to data state S10, the system will test whether those memory cells have a threshold voltage greater than or equal to Vv10. When programming memory cells to data state S11, the system will test whether those memory cells have a threshold voltage greater than or equal to Vv11. When programming memory cells to data state S12, the system will test whether those memory cells have a threshold voltage greater than or equal to Vv12. When programming memory cells to data state S13, the system will test whether those memory cells have a threshold voltage greater than or equal to Vv13. When programming memory cells to data state S14, the system will test whether those memory cells have a threshold voltage greater than or equal to Vv14. When programming memory cells to data state S15, the system will test whether those memory cells have a threshold voltage greater than or equal to Vv15.

In one embodiment, known as full sequence programming, memory cells can be programmed from the erased data state S0 directly to any of the programmed data states S1-S15. For example, a population of memory cells to be programmed may first be erased so that all memory cells in the population are in erased data state S0. Then, a programming process is used to program memory cells directly into data states S1, S2, S3, S4, S5, S6, S7, S8, S9, S10, S11, S12, S13, S14 and/or S15. For example, while some memory cells are being programmed from data state S0 to data state S1, other memory cells are being programmed from data state S0 to data state S2 and/or from data state S0 to data state S3, and so on. The arrows of FIG. 8 represent the full sequence programming. The technology described herein can also be used with other types of programming in addition to full sequence programming (including, bit not limited to, multiple stage/phase programming)

FIG. 9 illustrates that another embodiment of threshold voltage distributions corresponding to data states S0-S15 that can partially overlap since the error correction can handle a certain percentage of memory cells that are in error. Because of the size of the drawing, the references to the data states have been truncated such that 0 is used rather than S0, 1 is used rather than S1, 2 is used rather than S2, and so on.

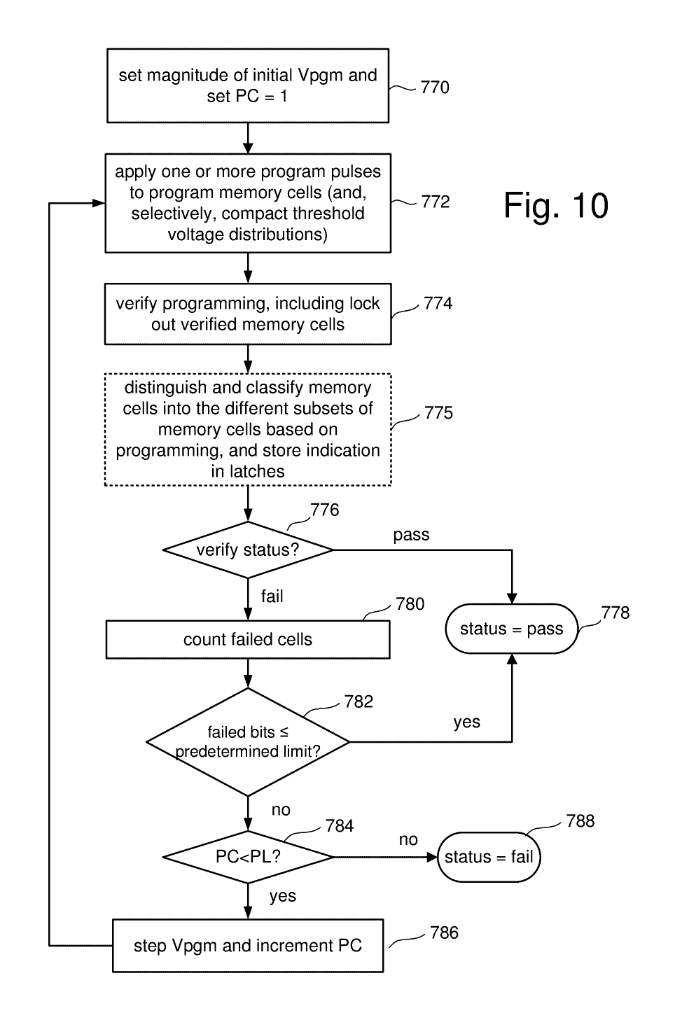

FIG. 10 is a flow chart describing one embodiment of a process for performing programming on memory cells connected to a common word line to one or more targets (e.g., also known as data states, programmed states or threshold voltage ranges). The process of FIG. 10 can be performed one or multiple times to program data to a set of memory cells. For example, the process of FIG. 10 can be used to program memory cells from S0 to any of programmed states S1-S15 in the full sequence programming of FIG. 8. The process of FIG. 10 can be used to program memory cells for any of the phases of a multi-phase programming process known in the art.

Typically, the program voltage applied to the control gate during a program operation is applied as a series of program pulses. Between programming pulses are a set of verify pulses to perform verification. In many implementations, the magnitude of the program pulses is increased with each successive pulse by a predetermined step size. In step 770 of FIG. 10, the programming voltage (Vpgm) is initialized to the starting magnitude (e.g., ˜12-16V or another suitable level) and a program counter PC maintained by state machine 112 is initialized at 1. In step 772, one or more program (voltage) pulses of the program signal Vpgm is applied to the selected word line (the word line selected for programming), so that it is applied to multiple NAND strings. In one embodiment, the group of memory cells being programmed concurrently are all connected to the same word line (the selected word line). The unselected word lines receive one or more boosting voltages (e.g., ˜7-11 volts) to perform boosting schemes known in the art. In step 772, the program pulse is concurrently applied to all memory cells connected to the selected word line so that the memory cells connected to the selected word line that are not inhibited are programmed concurrently. That is, they are programmed at the same time or during overlapping times (both of which are considered concurrent). In this manner all of the memory cells connected to the selected word line that are not inhibited will concurrently have their threshold voltage change. Additionally, step 772 includes applying compaction separately and at appropriate time(s), as described in more detail below.

In step 774, the appropriate memory cells are verified using the appropriate set of target levels to perform one or more verify operations. In one embodiment, the verification process is performed by testing whether the threshold voltages of the memory cells selected for programming have reached the appropriate verify reference voltage (Vv1, Vv2, Vv3, Vv15) Memory cells that are successfully verified to have reached their target state are locked out from further programming

In step 775, the system distinguishes and classifies memory cells into the different subsets of memory cells based on performance during programming, and stores an indication of the classification in latches 494. Step 775 is depicted in a dotted line because, in some embodiments, step 775 is not performed during every iteration of steps 772-786. In one embodiment, step 775 is only performed in one iteration of steps 772-786, and prior to step 775 being performed each iteration of step 772 applies one program pulse and subsequent to step 775 being performed each iteration of step 772 applies two program pulses of different magnitude.

In step 776, it is determined whether all the memory cells have reached their target threshold voltages (pass). If so, the programming process is complete and successful because all selected memory cells were programmed and verified to their target states. A status of “PASS” is reported in step 778. If, in 776, it is determined that not all of the memory cells have reached their target threshold voltages (fail), then the programming process continues to step 780.

In step 780, the system counts the number of memory cells that have not yet reached their respective target threshold voltage distribution. That is, the system counts the number of memory cells that have failed the verify process. This counting can be done by the state machine, the controller, or other logic. In one implementation, each of the sense blocks will store the status (pass/fail) of their respective cells. In one embodiment, there is one total count, which reflects the total number of memory cells currently being programmed that have failed the last verify step. In another embodiment, separate counts are kept for each data state.

In step 782, it is determined whether the count from step 780 is less than or equal to a predetermined limit. In one embodiment, the predetermined limit is the number of bits that can be corrected by ECC during a read process for the page of memory cells. If the number of failed cells is less than or equal to the predetermined limit, than the programming process can stop and a status of “PASS” is reported in step 778. In this situation, enough memory cells programmed correctly such that the few remaining memory cells that have not been completely programmed can be corrected using ECC during the read process. In some embodiments, step 780 will count the number of failed cells for each sector, each target data state or other unit, and those counts will individually or collectively be compared to a threshold in step 782.

In another embodiment, the predetermined limit can be less than the number of bits that can be corrected by ECC during a read process to allow for future errors. When programming less than all of the memory cells for a page, or comparing a count for only one data state (or less than all states), than the predetermined limit can be a portion (pro-rata or not pro-rata) of the number of bits that can be corrected by ECC during a read process for the page of memory cells. In some embodiments, the limit is not predetermined Instead, it changes based on the number of errors already counted for the page, the number of program-erase cycles performed or other criteria.

If number of failed memory cells is not less than the predetermined limit, than the programming process continues at step 784 and the program counter PC is checked against the program limit value (PL). Examples of program limit values include 20 and 30; however, other values can be used. If the program counter PC is not less than the program limit value PL, then the program process is considered to have failed and a status of FAIL is reported in step 788. If the program counter PC is less than the program limit value PL, then the process continues at step 786 during which time the Program Counter PC is incremented by 1 and the program voltage Vpgm is stepped up to the next magnitude. For example, the next pulse will have a magnitude greater than the previous pulse by a step size (e.g., a step size of 0.1-0.4 volts). After step 786, the process loops back to step 772 and another program pulse is applied to the selected word line. In one embodiment, the process of FIG. 10 is performed by decoders 114/124/132, code and parameter storage 113, power control module 116, sense blocks SB1, SB2, . . . , SBp, read/write circuits 128 at the direction of state machine 112 (and/or controller 122).

When storing four bits of data in each memory cell using sixteen data states, as depicted in FIGS. 8 and 9, the process of verification (see step 774 of FIG. 10) can slow down the programming process. For example, some systems will perform a verification operation for each of the fifteen possible programmed states S1-S15. Thus, each iteration (loop) of the process of FIG. 10 can include fifteen verify operations (e.g. fifteen verify pulses on the selected word line) during step 774. The large number of verify operations slows down the programming Therefore, some systems will only verify for a subset of programmed states that the memory cells could potentially be achieving. In some embodiments, the number of programmed states being verified at a given time depends on the width of the natural threshold distribution. Therefore, it is proposed to reduce the amount of time needed to verify by reducing the width of the threshold voltage distribution so that less data states need to be verified at a given time.

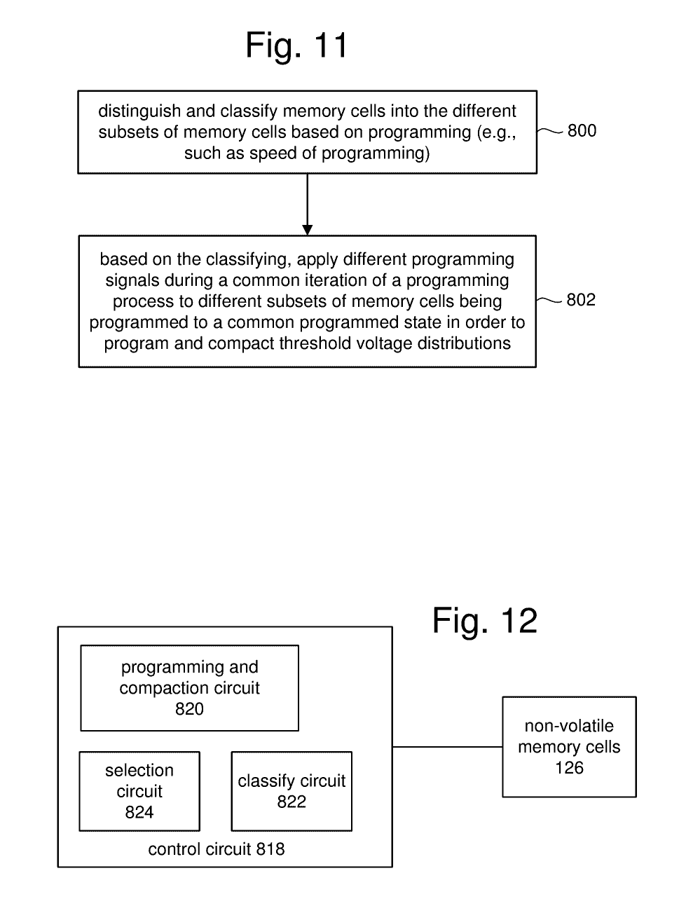

FIG. 11 is a flow chart describing one embodiment of a process for compacting threshold voltage distributions so that less data states need to be verified at a given time and the programming process completes quicker.

In step 800 of FIG. 11, the system distinguishes and classifies memory cells into the different subsets of memory cells based on performance during programming (e.g., such as speed of programming) For example, the system may distinguish fast programming memory cells from slow programming memory cells. Other attributes can also be used to distinguish subsets or memory cells. In one embodiment, step 800 is performed as step 775 of FIG. 10. The distinguishing and classifying can be performed once at or near the beginning of the programming process (or in the middle of the programming process), or multiple times throughout the programming process. The results of the distinguishing and classifying are stored in respective latches 494.

In step 802, based on the classifying, the system applies different programming signals during a common iteration of a programming process to different subsets of memory cells being programmed to a common programmed state in order to program and compact threshold voltage distributions. The different programming signals are customized to the subsets of memory cells. For example, slower programming memory cells can received higher magnitude programming voltages. In one embodiment, step 802 of FIG. 11 is performed as part of multiple iterations of step 772, where two (or more) program pulses are applied during each iteration of step 772. A lower magnitude program pulse is applied to fast programming memory cells and a higher magnitude program pulse is applied to slow programming memory cells in an attempt to speed up the programming of the to slow programming memory cells so that the threshold voltage distribution will become narrower.

FIG. 12 is a block diagram of one example set of components that can perform the process of FIG. 11. For example, FIG. 12 depicts control circuit 818 in communication with non-volatile memory cells 126. In one embodiment, memory cells 126 can include memory cells in a two dimensional structure or three dimensional structure (e.g., such as the structure depicted in FIGS. 4A-F). Any of various non-volatile technologies known in the art can be used to implement memory cells 126. One example implementation of control circuit 818 includes programming and compaction circuit 820, classify circuit 822, and selection circuit 824. Programming and compaction circuit 820, which is in communication with the non-volatile memory cells 126, is used to program the non-volatile memory cells 126 by providing programming signals to the non-volatile memory cells, and to narrow the threshold voltage distribution. Selection circuit 824, which is connected to the programming and compaction circuit 820, selectively directs the programming circuit to provide separate programming signals to the plurality of groups/subsets of non-volatile memory cells while programming the plurality of groups/subsets to a common data state during a common programming process. In one embodiment, programming circuit 820 and selection circuit 824 perform step 802 of FIG. 11 (which can include performing or all or part of the process depicted in FIG. 10)). Classify circuit 822 is used to classify the memory cells, or otherwise distinguish them between different groups of memory cells based on programming performance. In one embodiment, classify circuit 822 performs step 800 of FIG. 11.

In one example implementation, programming and compaction circuit 820, classify circuit 822, and selection circuit 824 are electrical circuits that are electrical circuits implemented on the same semiconductor chip as non-volatile memory cells 126. In other embodiments, programming and compaction circuit 820, classify circuit 822, and selection circuit 824 can be implemented on a separate semiconductor chip. In one embodiment, programming and compaction circuit 820, classify circuit 822, and selection circuit 824 are implemented as one single electrical circuit that can perform the three functions. For example, that single electrical circuit is referred to as control circuit 818 in FIG. 12. In one example, control circuit 818 can be implemented by state machine 112, control circuitry 110, controller 122, any one or more of the control circuits described above, or another circuit in the memory system.

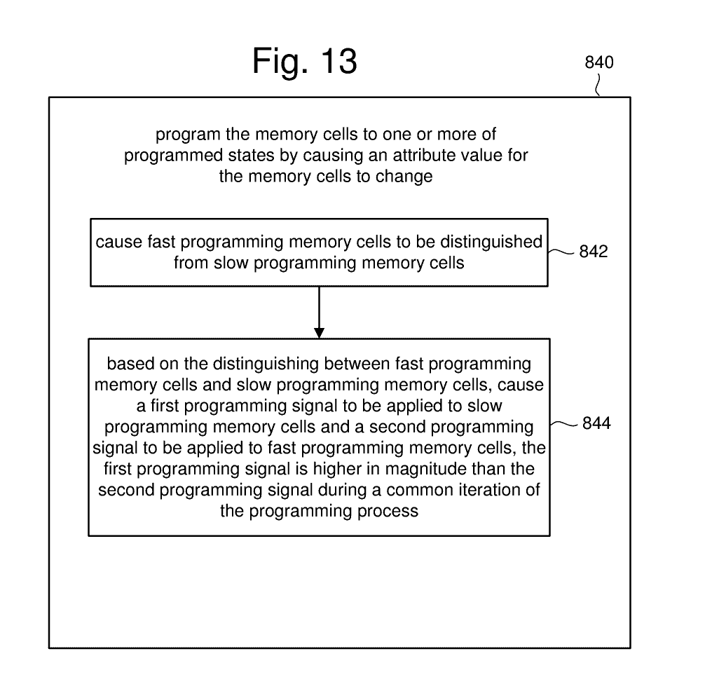

FIG. 13 is a flowchart describing one example implementation of the process of FIG. 11 for an embodiment in which the depicted process is performed by controller 122, a host device, or another device that is external to memory die 108. Step 840 includes programming selected memory cells to one or more programmed states by causing an attributive value (e.g., threshold voltage, magnetism, resistance, charge, etc.) for the memory cells to change. For example, controller 122 will send instructions to memory die 108 to apply programming pulses in order to change a threshold voltage of the memory cells to any one of the data states depicted in FIG. 8. In one embodiment, the programming of step 840 includes sub-steps 842 and 844. In sub-step 842, controller 122 causes fast programming memory cells to be distinguished from slow programming memory cells. For example, controller 122 can send instructions to memory die 108 to perform one or more sense operations (as discussed herein) in order to distinguish and classify fast programming memory cells and slow programming memory cells. In sub-step 844, based on distinguishing between the fast programming memory cells and slow programming memory cells, controller 122 causes a first programming signal to be applied to slow programming memory cells and a second programming signal to be applied to fast programming memory cells. The first programming signal is higher in voltage magnitude than the second programming signal during a common iteration of the programming process. For example, looking back at FIG. 10, steps 772-786 are a repeating loop. Each repeat of that loop is an iteration of the programming process. During one iteration of steps 772-786, step 772 include applying multiple programming pulses (one programming pulse for the first programming signal and another programming pulse for the second programming signal). Those programming pulses, during the same iteration of the programming process, will have different magnitudes as discussed herein. Sub-step 844 includes controller 122 sending instructions to memory die 108 to apply the programming pulses.

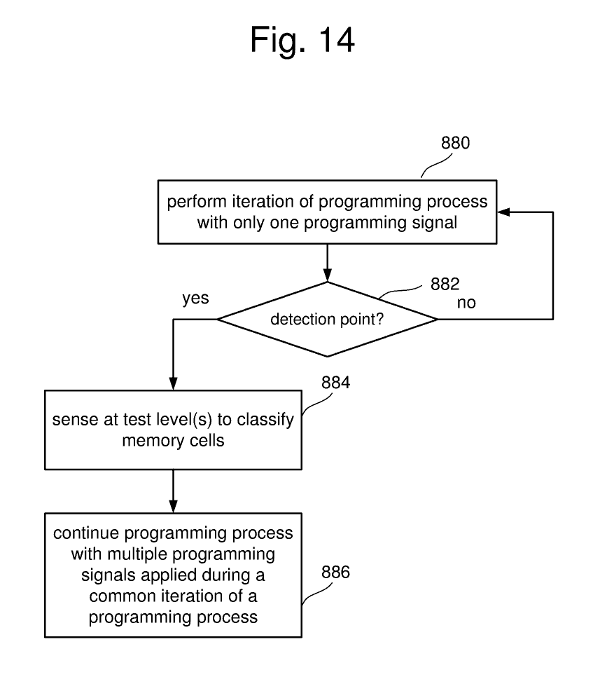

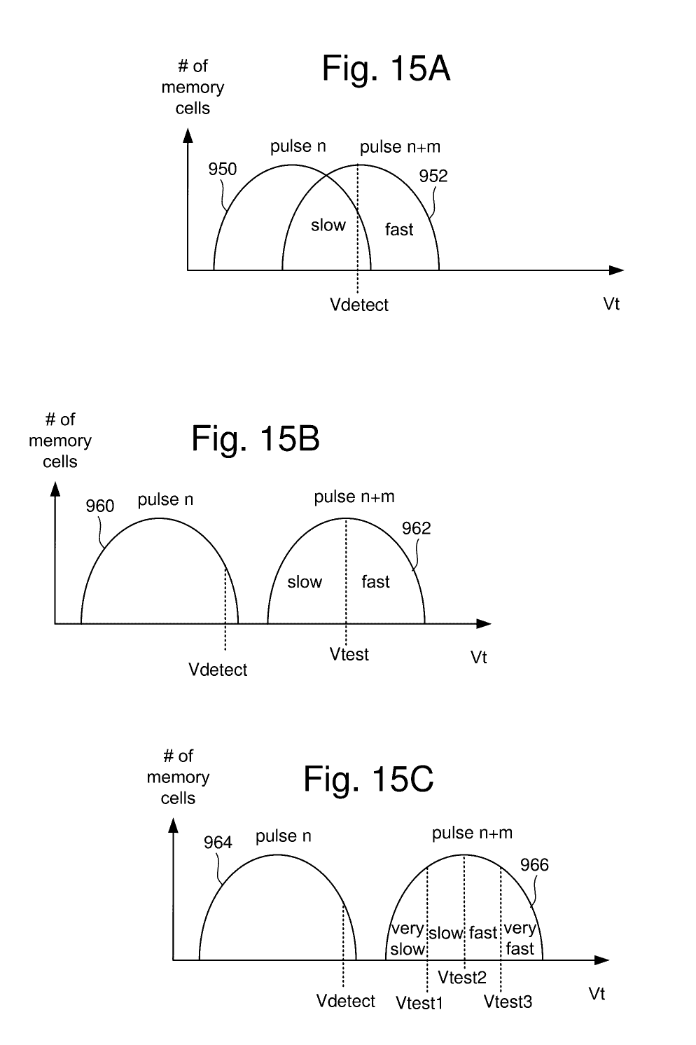

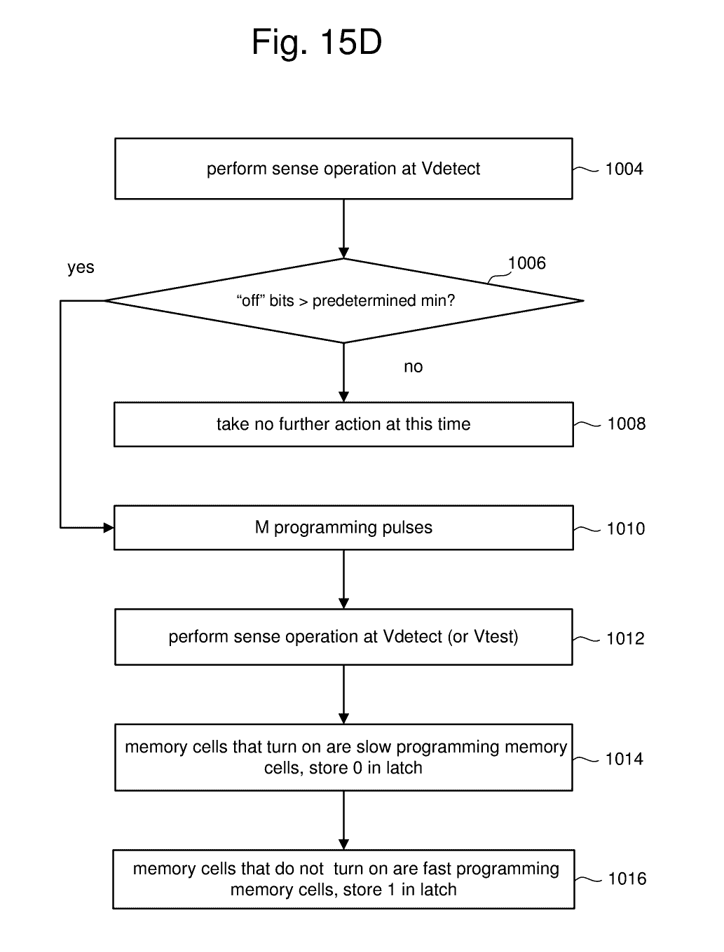

FIG. 14 is a flowchart describing one embodiment of the process for implementing the distinguishing, classifying and compaction, as discussed herein (e.g., see FIGS. 11-13). In step 880, the system performs an iteration of the programming process (e.g., one pass through step 772-786 of FIG. 10) with only one programming signal. That is, for example, when performing step 772 only one programming pulse is applied. In step 882, it is determined whether the population of memory cells being programmed have reached a detection point. There are many detection points that can be used, some of which are discussed below. If the population of memory cells has not reach the detection point, then the process loops back to step 880 and another iteration of the programming process (e.g., one pass through step 772-786 of FIG. 10) is performed with only one programming signal (e.g., one programming pulse applied in Step 772). If, however, the population of memory cells being programmed has reached a detection point (step 882), then in step 884 the system will perform a sense operation at one or more test levels in order to classify the memory cells being programmed. In one embodiment, step 884 is only performed once for each time a population memory cells are being programmed with a set of data. More details of the detection point (step 882) and the one or more test levels (step 884) are discussed below with respect to FIGS. 15A-17C (see Vdetect, Vtest, Vtest1, Vtest2 and Vtest3). In step 886, the programming process (e.g., the flow chart of FIG. 10) will continue with multiple programming signals being applied during each iteration of the programming process. For example, after performing step 884, the iterations of the programming process will include step 772 applying multiple programming pulses. The different programming pulses will be applied to different groups of memory cells based on the classification in step 884. More details are provided below. Note that the process in FIG. 14 can be performed by control circuit 818, state machine 112, control circuitry 110, controller 122 and/or any of the one or more control circuits described above.

There are many different ways to distinguish and classify memory cells into different groups (e.g., fast and slow) that are suitable for the technology described herein. FIGS. 15A, 15B, 15C, 15D, 16A, 16B, 17A, 17B and 17C describe a set of example embodiments. However, the technology disclosed herein is not limited to these exact processes for distinguishing and classifying the memory cells. Additionally, the technology disclosed herein is not limited to distinguishing and classifying based on fast/slow. In some embodiments, the processes for implementing FIGS. 15A, 15B, 15C, 15D, 16A, 16B, 17A, 17B and 17C is performed by classify circuit 822, control circuit 818, state machine 112, control circuitry 110, controller 122 and/or any of the one or more control circuits described above. The processes of FIGS. 15A, 15B, 15C, 15D, 16A, 16B, 17A, 17B and 17C are example implementations of step 800 of FIG. 11.

FIG. 15A shows two threshold voltage distributions 950 and 952. The graph of FIG. 15A also identifies a particular threshold voltage Vdetetc. The system will monitor the threshold voltages of the memory cells being programmed until a predetermined minimum number of memory cells have their threshold voltage higher than Vdetect. This condition is depicted by threshold voltage distribution 950. FIG. 15A indicates that threshold voltage distribution 950 occurs after the nth programming pulse. After the predetermined minimum number of memory cells have a threshold voltage greater than Vdetect, the system will perform M more iterations of the programming process of FIG. 10 such that M more programming pulses are applied. Threshold voltage distribution 952 indicates the state of the memory cells after n+m programming pulses have been applied. At this point, the system will perform a sensing operation to determine which memory cells have a threshold voltage less than Vdetect and which memory cells have a threshold voltage greater than Vdetect. For example, if Vdetect volts are applied to the selected word line for the memory cells being programmed, those memory cells that turn on will have threshold voltages less than Vdetect and those memory cells that do not turn on will seem to have threshold voltages greater than Vdetect. In one embodiment, those memory cells having a threshold voltage less than Vdetect are considered slow programming memory cells and those memory cells have a threshold voltage greater than Vdetect are considered fast programming memory cells.

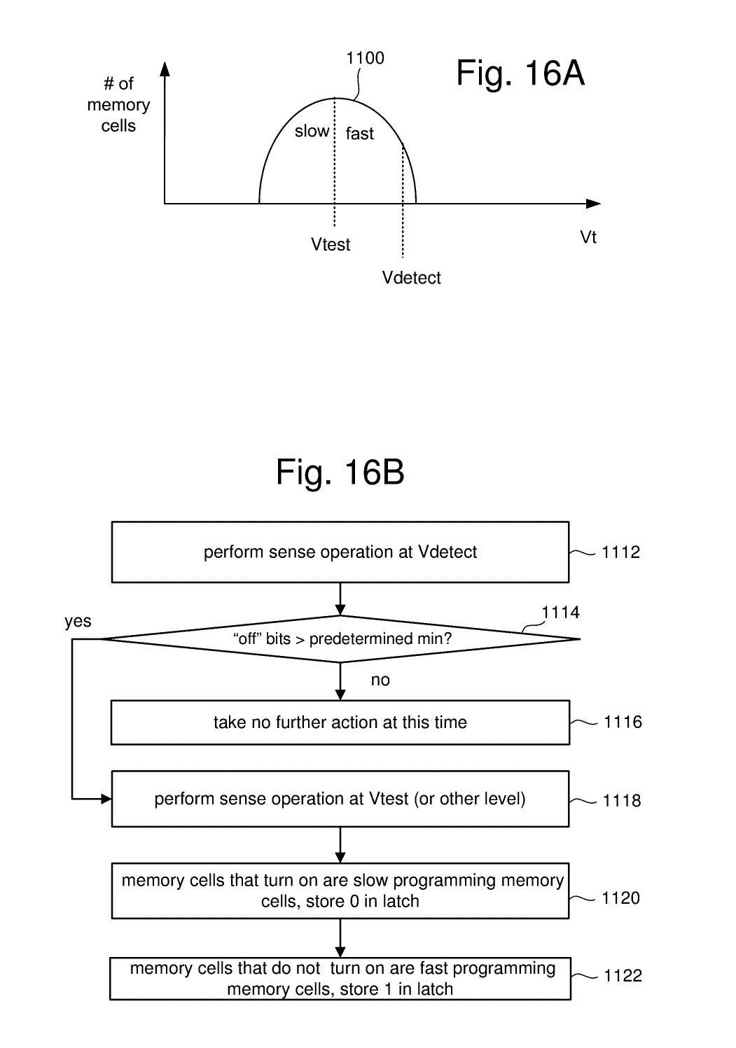

FIG. 15B depicts an alternative to the embodiment of FIG. 15A. FIG. 15B shows two threshold voltage distributions 960 and 962. FIG. 15B also indicates two threshold voltages Vdetect and Vtest. When at least a predetermined minimum number of memory cells have their threshold voltage greater than Vdetect, as depicted by threshold voltage 960 after the nth pulse, the system will apply m more programming pulses (ie m more iterations of the process of FIG. 10). The threshold voltage distribution 962 represents the distribution of threshold voltages after n+m programming pulses. At this point, the system will perform a test to see which memory cells have a threshold voltage less than some determined test point Vtest. Those memory cells have a threshold voltage less than Vtest are considered slow programming memory cells and those memory cells having a threshold voltage greater than Vtest are considered fast programming memory cells. In the embodiment depicted in FIG. 16B, Vtest is that the halfway point of the simulated or expected threshold voltage distribution; however, in other embodiments, the test point Vtest can be at other threshold voltages.

FIG. 15C depicts an alternative to the embodiment of FIG. 15A that classifies the memory cells into four groups: very slow, slow, fast and very fast. In other embodiments, more or less than four groups can be implemented. FIG. 15C shows two threshold voltage distributions 964 and 966. FIG. 15B also indicates four threshold voltages: Vdetect, Vtest1, Vtest2, Vtest3 and Vtest4. When at least a predetermined minimum number of memory cells have their threshold voltage greater than Vdetect, as depicted by threshold voltage 964 after the nth pulse, the system will apply m more programming pulses (ie m more iterations of the process of FIG. 10). The threshold voltage distribution 966 represents the distribution of threshold voltages after n+m programming pulses. At this point, the system will perform a test to see which memory cells have a threshold voltage (a) less than Vtest1, (b) greater than Vtest 1 and less than Vtest2, (c) greater than Vtest2 and less than Vtest3, or (d) greater than Vtest3. Those memory cells have a threshold voltage less than Vtest1 are considered very slow programming memory cells. Those memory cells have a threshold voltage greater than Vtest1 and less than Vtest2 are considered slow programming memory cells. Those memory cells have a threshold voltage greater than Vtest2 and less than Vtest3 are considered fast programming memory cells. Those memory cells have a threshold voltage greater than Vtest3 are considered very fast programming memory cells.

FIG. 15D is a flowchart describing one embodiment of a process for classifying fast and slow programming memory cells. The process of FIG. 15D can be used to implement the embodiments of FIG. 15A or 15B (in, with some changes, the embodiment of FIG. 15C), as well as other embodiments. In step 1004, the system will perform a sense operation at Vdetect. In step 1006, the system determines whether the number of “off” bits (the number of memory cells that did not turn on because the threshold voltage is greater than Vdetect) is greater than a predetermined minimum number. If not, then no further action is taken at this time with respect to classifying memory cells (step 1008). If the number of “off” bits are greater than the predetermined minimum, then in step 1010 the system will perform m more programing pulses (e.g., m more iterations of the programming process of FIG. 10—see loop comprising steps 772-786). In step 1012, a sense operation is performed at Vdetect (after m programming pulses) for the memory cells being programmed. Alternatively, the sense operation will be performed at Vtest (or Vtest1, Vtest2 abdVtest3). In step 1014, memory cells that turn on in response to Vdetect or Vtest have a threshold voltage below Vdetect or Vtest and, therefore, are considered slow programming memory cells. For those slow programming cells, a zero is stored in the appropriate latch. Looking back at FIG. 3C, each of the sense blocks 129 includes a set of data latches 494. In one embodiment, there are three data latches for each bit line. In another embodiment, more than three data latches can be used for each bit line. One of those data latches is used to store a zero for slow programming memory cells and a one for fast programming memory cells. Other encoding of fast and slow can also be used. In one embodiment, the data will remain in a latch for the entire programming process (the process of FIG. 10). In other embodiments, the indication of fast or slow can remain in the latches for the life of device. In step 1016, memory cells that do not turn on in response to the sense operation at Vdetect or Vtest (or other level) are considered fast programming memory cells. For those fast programming memory cells, logic one is stored in the appropriate latch.

FIG. 16A depicts a threshold voltage distribution 1100, and two specific threshold voltage points Vtest and Vdetect. When a predetermined number of memory cells have a threshold voltage greater than Vdetect, then the system will test whether all memory cells being programmed to have a threshold voltage greater than or less than Vtest. Those memory cells having a threshold voltage less than Vtest are considered slow programming memory cells. Those memory cells having a threshold value voltage greater than Vtest are considered fast programming memory cells.

FIG. 16B is a flow chart describing one embodiment for performing the classification of fast and slow programming memory cells based on the graph of FIG. 16A. In step 1112, the system performs a sense operation at Vdetect. If (step 1114), the system determines that the number of off bits (memory cells that did not turn on in response to Vdetect because their threshold voltage is greater than Vdetect) is not greater than a predetermined minimum number, then no further action is taken at this time as part of the classification (step 1116). If (step 1114), the system determines that the number of off bits (memory cells that did not turn on in response to Vdetect because their threshold voltage is greater than Vdetect) is greater than a predetermined minimum number, then a sense operation is performed at Vtest for memory cells being programmed. In step 1120, memory cells that turn on in response to sense operation at Vtest (because that threshold voltage is less than Vtest) are considered slow programming memory cells (see FIG. 16A). For those slow programming memory cells, a zero is stored in the appropriate latch. In step 1122, memory cells that do not turn on in response to the sense operation at Vtest (because their threshold voltage is greater than Vtest) are considered fast programming memory cells. For fast programming memory cells, data one is stored in the appropriate latch.

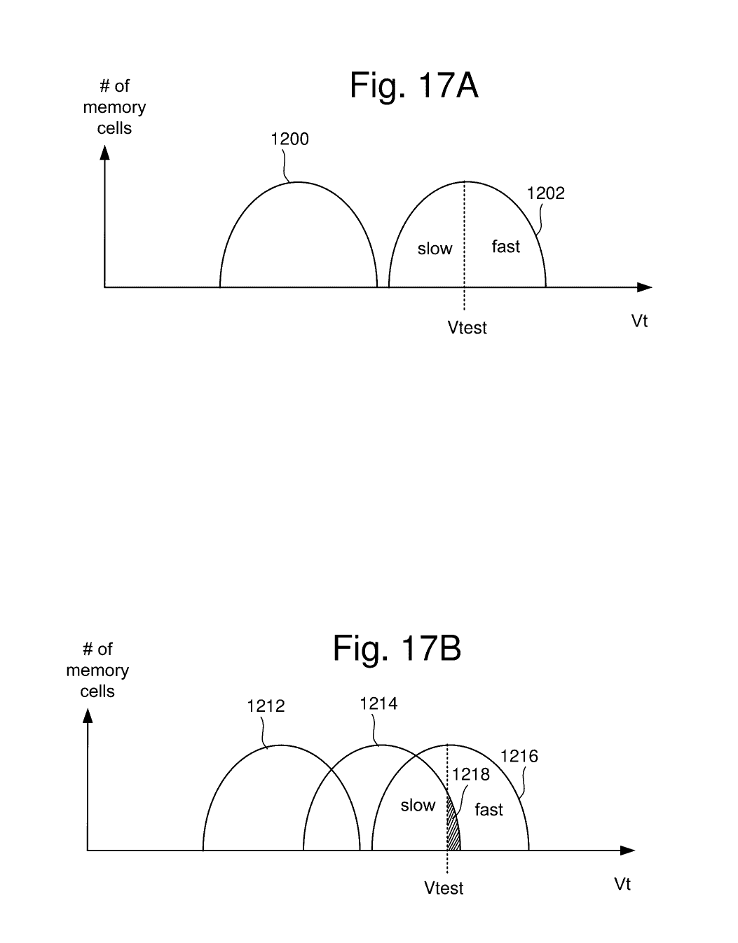

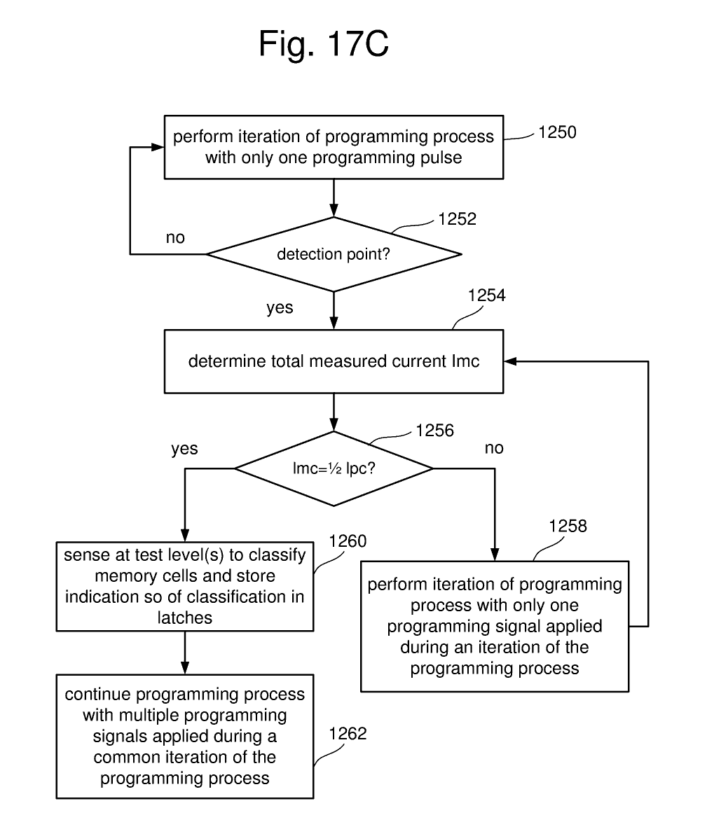

FIGS. 17A-C depict another embodiment of distinguishing and classifying memory cells. FIG. 17A depicts threshold voltage distributions 1200 and 1202, as well as threshold voltage Vtest. As discussed above, and graphically depicted in FIG. 4F, the NAND strings of a block are connected to a common cell source line (e.g., see common source line SL of FIG. 4F). When performing a sense operation, if each of the memory cells connected to the selected word line (one memory cell per NAND string) turned on because their threshold voltage is less than the voltage applied to the selected word line, then the current at the common source line would be the sum of the currents through all the NAND strings. This is referred to herein as the total potential current Ipc. The current measured at the common source line SL is referred to as the total measured current Imc. In one embodiment, the system will include a circuit for measuring current at the common source line. In another embodiment, each of the sense amplifiers connected to each of the bitlines will have a circuit for detecting current and reporting that detected level to the state machine or other component. If the memory cells are in the condition depicted by threshold voltage 1200 and the voltage Vtest is applied to the selected word line, then the total measured current Imc would be equal to the total potential current Ipc. As the population of memory cells receive additional programming such that some of the memory cells have their threshold voltages increase to a level greater than Vtest, then the total measured of current Imc will become less than the total potential current Ipc because some memory cells (that have a threshold voltage greater than Vtest) will turn off. The embodiment of FIG. 17A seeks to determine at what time the total measured current Imc is equal to half of the total potential current Ipc. Threshold voltage distribution 1202 represents the condition when Imc=½Ipc. At that point, those memory cells having a threshold voltage below Vtest are considered slow programming memory cells and those memory cells having a threshold voltage greater than Vtest are considered fast programming memory cells, as depicted by the text of FIG. 17A.

FIG. 17B is an alternative to the embodiment of FIG. 17A. In one implementation of FIG. 17A, the system will check the total measured current at every iteration of the programming process. FIG. 17B provides an embodiment that removes the need to measure the total measured current at every iteration of the programming process. The graph of FIG. 17B shows three threshold distributions: 1212, 1214, and 1216. When the memory cells are in threshold voltage 1212, total measured current Imc should be equal to the total potential current Ipc. However, rather than checking the total measured current I mc at every iteration of the programming process, the system will start out by determining whether a predetermined minimum number of memory cells have a threshold voltage greater than Vtest. When the population of memory cells does have a predetermined minimum number of memory cells having a threshold voltage greater than Vtest, then the system will start measuring Imc and comparing Imc to Ipc. This condition is noted by threshold voltage distribution 1214, which shows shaded region 1218 representing memory cells with a threshold voltage greater than Vtest. When this condition occurs (threshold voltage distribution 1214), the system will begin to check at each iteration of the programming process whether the total measured current Imc is equal to half of the total potential current Ipc. Threshold voltage distribution 1216 represents the condition when Imc=½Ipc. At that point, those memory cells having a threshold voltage below Vtest are considered slow programming memory cells and those memory cells having a threshold voltage greater than Vtest are considered fast programming memory cells, as depicted by the text of FIG. 17B.

FIG. 17C is a flowchart describing one embodiment of a process for implementing the embodiments of FIGS. 17A and 17B in order to distinguish and classify memory cells based on performance during programming. In step 1250, the system performs an iteration of the programming process (e.g., one pass through steps 772-786 of FIG. 10) with only applying one programming pulse during step 772. In step 1252, the system determines whether the population of memory cells has reached a detection point. In the embodiment of FIG. 17A, the detection point can be the first iteration of the programming process or the nth iteration of the programming process. In the embodiment of FIG. 17B, the detection point is when a predetermined minimum number of memory cells having a threshold voltage greater than Vtest. Other detection points can also be used. If the system has not reached a detection point, then the process loops back to step 1250 and continues to perform another iteration of the programming process with only applying one programming pulse in step 772.

If the population of memory cells has reached the detection point (step 1252), then in step 1254 the system determines the total measured current Imc as experienced at the common source line (e.g., SL of FIG. 4F). In step 1256, it is determined whether the total measured current Imc is equal to half the total potential current Ipc. If not, then in step 1258, the system will perform another iteration of the programming process with only applying one programming pulse during step 772 of FIG. 10. After step 1258, the process loops back to step 1254.

If in step 1256, it is determined that the total measured current Imc is equal to half of the total potential current Ipc, then in step 1260 the system will sense the memory cells at one or more test levels to classify the memory cells. That classification is stored in latches 494. In one embodiment, the system only will detect and classify fast versus slow programming memory cells. In other embodiments, there can be more than two classifications (e.g., very fast, fast, slow, very slow, etc.). In step 1262, the system continues the programming process with multiple programming signals being applied during a common iteration of the programming process. For example, the process in FIG. 10 will continue, and each iteration will include step 772 applying multiple programming pulses with different voltage magnitudes to account for the different classifications of memory cells. The applying the multiple programming pulses with different voltage magnitudes is performed during a single iteration of step 772.

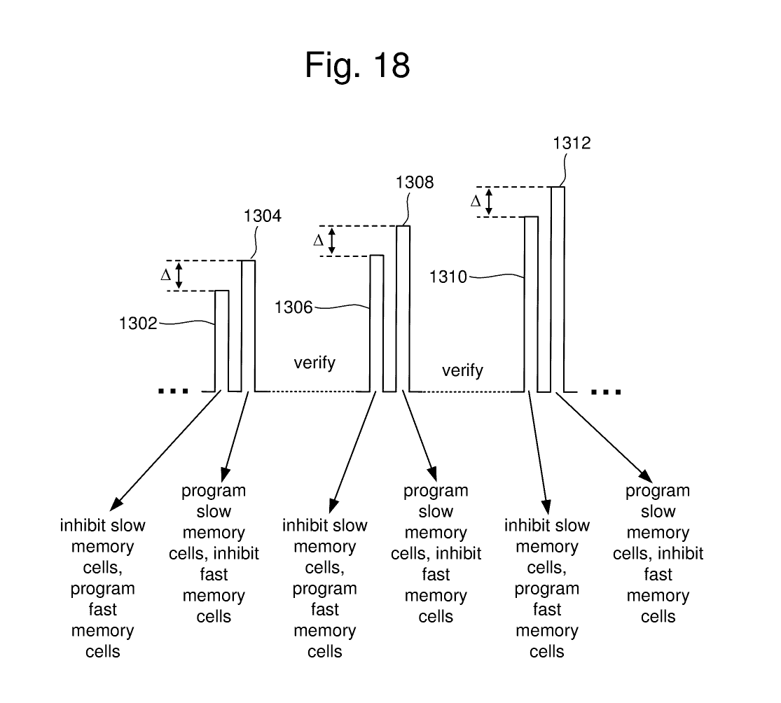

FIGS. 15A, 15B, 15C, 15D, 16A, 16B, 17A, 17B and 17C describe examples of how to distinguish between fast programming memory cells and slow programming memory cells (see step 800 of FIG. 11). FIGS. 18-22 provide examples of how to compact/narrow the threshold voltage distributions based on knowing which memory cells are fast programming cells and which memory cells are slow programming cells by applying different programming signals during a common iteration of a programming process to the fast programming cells and the slow programming cells. (see step 802 of FIG. 11). In one embodiment, the functions described by FIGS. 18-22 are performed by programming and compaction circuit 820, control circuit 818, state machine 112, control circuitry 110, controller 122, or any of the one or more control circuits described above.

FIG. 18 depicts a series of programming pulses such that in each iteration of the programming process the system will apply two programming pulses: one programming pulse of lower magnitude will be applied to the fast programming memory cells and one programming pulse of higher magnitude will be applied to slower programming cells. By applying a higher voltage programming pulse to the slower programming memory cells, the intent is to speed up the programming of the slower programming memory cells so that the threshold voltage will be compacted or narrowed. For example, FIG. 18 shows programming pulse 1302 and programming pulse 1304. Programming pulse 1302 is a lower voltage magnitude programming pulse as compared to programming pulse 1304. Programming pulse 1302 and programming pulse 1304 are both applied to the same common word line during the same iteration/performance of step 772. First programming pulse 1302 is applied. While programming pulse 1302 is applied, slow programming memory cells are inhibited (e.g., by raising the bit line voltage Vb1 to Vdd) and fast programming memory cells are allowed to program (e.g., the bit line voltage Vb1 is set at zero volts). While programming pulse 1304 is applied, slow programming memory cells are allowed to program (e.g., the bit line voltage Vb1 is set at zero volts) and fast programming memory cells are inhibited (e. e.g., by raising the bit line voltage Vb1 to Vdd). The voltage magnitude of programming pulse 1304 is greater than the voltage magnitude of programming pulse 1302 by A. In one embodiment, A equals 1.5 volts. In other embodiments, A can have other values. In some embodiments, A is programmable or tunable dynamically during, after or before programming processes. After applying programming pulses 1302 and 1304 in step 772, the system will perform verify operations in step 774.

In the next iteration of the programming process FIG. 10, step 772 will include applying programming pulses 1306 and 1308. The magnitude of programming pulse 1308 is greater than the magnitude of programming pulse 1306 by Δ. The magnitude of programming pulse 1306 is greater than the magnitude of programming pulse 1302 by ΔVpgm. In one embodiment ΔVpgm is equal to 0.2 volts. Programming pulse 1306 is used to program fast programming memory cells (inhibit slow memory cells and allow fast programming memory cells to program). Programming pulse 1308 is applied to program slow programming memory cells (allows slow programming memory cells to program and inhibit fast programming memory cells). After applying programming pulses 1306 and 1308 in step 772 of FIG. 10., the system will perform one or more verify operations in step 774.

In the next iteration of step 772, the system applies programming pulses 1310 and 1312. The magnitude of programming pulse 1312 is greater than the magnitude of programming pulse 1310 by Δ. The magnitude of programming pulse 1310 is greater than the magnitude of programming pulse 1306 by ΔVpgm. Programming pulse 1310 is applied to program fast programming memory cells (inhibit slow programming memory cells and allow fast programming memory cells to program). Programming pulse 1312 is applied to program slow programming memory cells (allow slow programming memory cells to program and inhibit fast programming memory cells). After applying programming pulses 1310 and 1312, the system performs one or more verify operations, and the programming process of FIG. 10 will continue.

During each iteration in step 772, for the embodiment of FIG. 18, the two programming pulses (e.g., programming pulse 1302 and programming pulse 1304) represent the different programming signals. The first programming pulse is part of a first programming signal. The second programming pulse is part of a second programming signal. In one embodiment, the first programming signal includes the first pulse of each iteration (e.g., programming pulse 1302, 1306, 1310, . . . ) and the second programming signal is the second programming pulse of each iteration (e.g., programming pulse 1304, 1308, 1312, . . . ). Thus, the different groups or subsets of memory cells (e.g., fast and slow memory cells) will receive different voltage magnitudes. That is, the system will provide different voltages magnitudes to the different subsets of memory cells being programmed to a common programed or data state. For example, a slow memory cell and fast memory cell both being programmed to the same data state will receive programming pulses at different magnitudes. Additionally, the programming pulses are applied at different times. In the example of FIG. 18, the lower magnitude programming pulse is applied first and the higher magnitude programming pulse is applied second. In other embodiments, the higher magnitude programming pulse can be applied first and the lower magnitude programming pulse can be applied second. Note that in one embodiment, A (the difference in voltage magnitude between the higher magnitude programming pulse and the lower magnitude programming pulse) can be tunable based on performance of the population of memory cells, performance of the population of slow memory cells, performance of the population of fast memory cells or another metric.

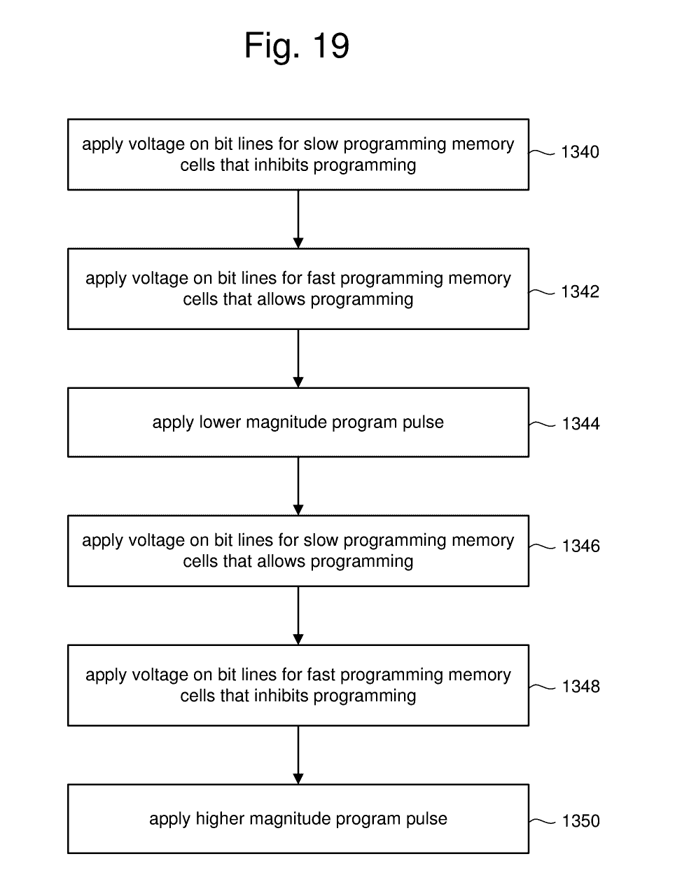

FIG. 19 is a flowchart describing one embodiment of a process for performing the compaction of threshold voltages by applying the different programming signals as per the embodiment of FIG. 18. That is, the process of FIG. 19 is one example implementation of step 802 of FIG. 11 based on the embodiment of FIG. 18. In step 1340, the system applies a voltage on the bit lines for slow programming memory cells that inhibits programming. In step 1342, the system applies a voltage on the bit lines for fast programming memory cells that allows programming. In step 1344, the system applies the lower magnitude programming pulse. In step 1346, the system applies a voltage on the bit lines for slow programming memory cells that allows programming. In step 1348, the system applies a voltage on the bit lines for fast programming memory cells that inhibits programming. In step 1350, the system applies the higher magnitude programming pulse.

In one embodiment, the process of FIG. 19 is performed during each iteration of step 772 of FIG. 10. For example, the process of FIG. 19 will first be performed for programming pulses 1302 and 1304. Subsequently, the process of FIG. 19 will be performed again for the programming pulses 1306 and 1308, and so on. In one alternative, when applying the programming pulse to the fast programming memory cell (e.g., step 1346), the slower programming memory cells will are not inhibited from programming

FIG. 18 shows two programming pulses applied during each iteration of the programming process. In other embodiments, more than two programming pulses can applied during each iteration of the programming process. For example, the memory cells can be divided in X groups (where X=2, 3, 4, . . . ) and each iteration of the programming process will include applying X program pulses (ie during step 772 of FIG. 10), one programming pulse per group.

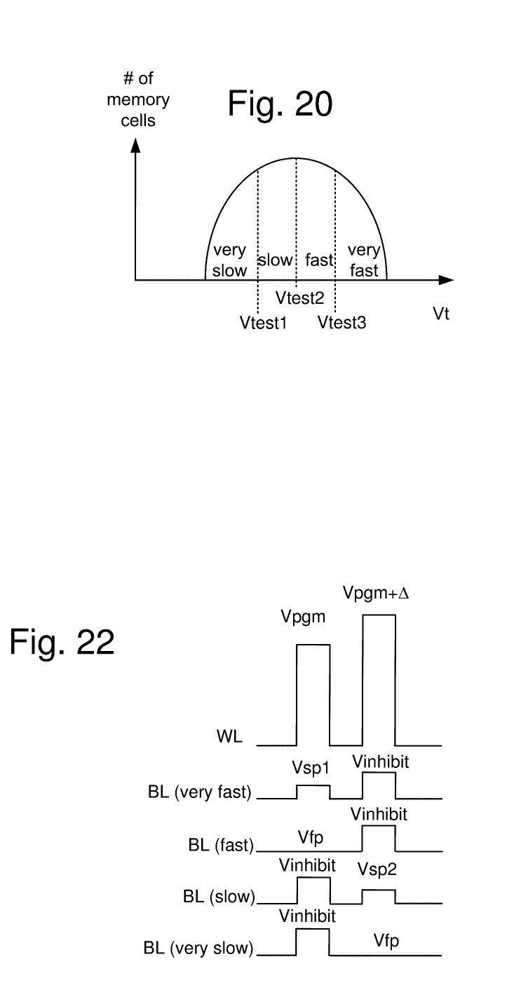

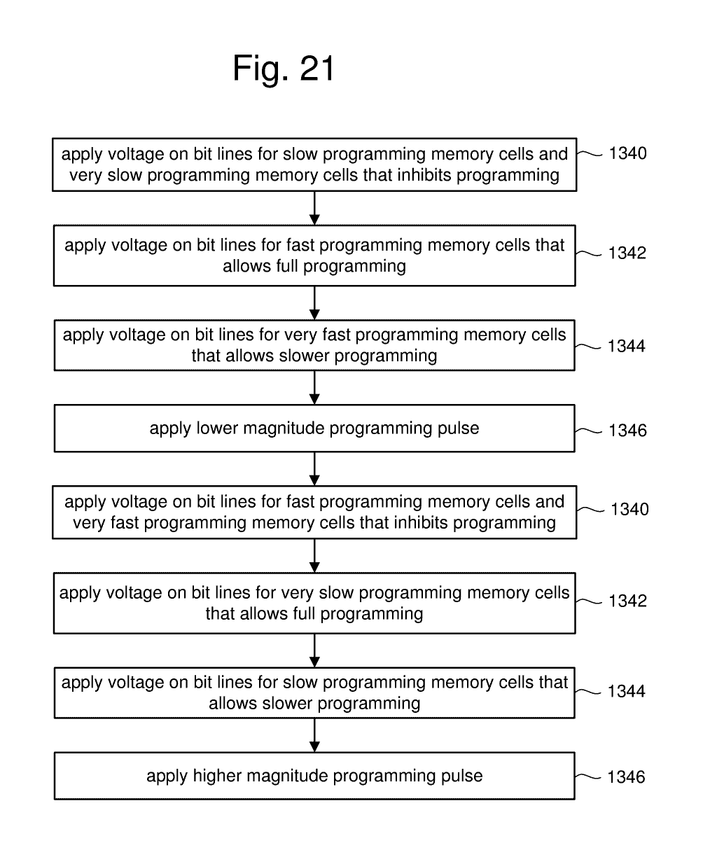

In the embodiment of FIGS. 18 and 19, memory cells will have their programming sped up or slowed down based on changing the magnitude of the programming signal applied to the selected word line. Another means for changing the speed of programming is to change the voltage on the bit line. FIGS. 20, 21 and 22 depict an embodiment which changes programming speed by a combination of adjusting the magnitude of the programming pulse applied to the word line and adjusting the voltage applied to the bit line. In this embodiment, the memory cells can be classified into two or more groups. For example, FIG. 20 depicts a threshold voltage distribution with memory cells distinguished and classified into four groups: very slow, slow, fast and very fast based on voltages Vtest1, Vtest2 and Vtest3, discussed above. In one example implementation, one set of programming pulses (higher voltage magnitude programming pulses) are used to program very slow and slow memory cells. Another set of programming pulses (lower voltage magnitude programming pulses) are used to program fast and very fast programming memory cells. To make slow programming memory cells program at the same pace as the very slow programming memory cells, an adjustment in bit line voltage will be used. To make very fast programming memory cells program at the same pace as the fast programming memory cells, an adjustment of the bitline voltage will be used. This process is explained by the flowchart at FIG. 21.

In step 1340 of FIG. 21, the system applies a voltage on the bit lines for slow programming memory cells and very slow programming memory cells that inhibits programming for those memory cells. In step 1342, the system applies a voltage on the bit lines for fast programming memory cells that allows full programming. For example, zero volts can be applied to those bit lines. In step 1344, the system applies a voltage on the bit lines for very fast programming memory cells that allows for slower programming. That means that the very fast programming memory cells will not be inhibited and some programming will occur. However, a bitline voltage less than the inhibit bitline voltage and greater than the full programming bitline voltage will be applied, such as one volt, to allows the very fast programming memory cells to program slower than the fast programming memory cells. In step 1346, the lower voltage magnitude programming pulse is applied. In one embodiment, the programming pulses of FIG. 18 can be applied as part of the process of FIG. 21. In that embodiment, step 1346 includes applying programming pulse 1302, programming pulse 1306 or programming pulse 1310.

In step 1340 of FIG. 21, the system applies a voltage on the bit lines for fast programming memory cells and very fast programming memory cells that inhibits programming. For example, the bit lines will receive Vdd (e.g., 3.5-5 volts). In step 1342, the system applies a voltage on the bit lines for very slow programming memory cells that allows full programming. For example, these bit lines will receive zero volts. In step 1344, the system applies a voltage on the bit lines for slow programming memory cells that allow slower programming (e.g., the same bit line voltage applied in step 1344). One example includes applying one volt to the bit line. In step 1346, the higher magnitude programming pulse is applied. For example, programming pulse 1304, 1308 or 1312 can be applied. Thus the process in FIG. 21 allows four groups to be differentiated by using only two different types of programming signals. The embodiment of FIG. 21 includes providing different programming signals and providing different bitline voltages to the different subsets/groups of memory cells being programmed to a common programmed state (e.g., S1-S15).

FIG. 22 is a timing diagram showing the behavior of the word line signal “WL,” the bit line signal for very fast programming memory cells “BL (very fast),” the bit line for fast programming memory cells “BL (fast),” the bit line for slow programming memory cells “BL (slow)” and the bit line for very slow programming memory cells “BL (very slow)” during the process of FIG. 21. FIG. 22 shows behavior during one iteration of step 772 of FIG. 10, which includes applying two programming pulses, one at Vpgm and another programming pulse at Vpgm+Δ.

When applying the first programming pulse of Vpgm, the bit line voltage for very fast programming memory cells BL (very fast) is at the voltage Vsp1 (e.g., one volt) which allows slower programming; the bit line voltage for fast programming memory cells BL (fast) is at Vfp (e.g., zero volts), which is set to allow full programming; the bit line voltage for slow programming memory cells BL (slow) is at Vinhibit (e.g., 3.5-5 volts), which is set to inhibit any programming; and the bit line voltage for very slow programming memory cells BL (very slow) is also set at Vinhibit.

During the second programming pulse at Vpgm+Δ, the bit line voltage for very fast programming memory cells BL (very fast) is set at Vinhibit; the bit line voltage for fast programming memory cells BL (fast) is set at Vinhibit; the bit line voltage for slow programming memory cells BL (slow) is set for Vsp2 (e.g., one volt); and the bit line volatge for very slow programming memory cells (BL (very slow) is set at Vfp. In one embodiment, Vsp1=Vsp2. In another embodiment, Vsp1−Vsp2.

In some embodiments that include two (or more) programming pulses during an iteration of the programming process, the programming signal Vpgm steps up (see step 786 of FIG. 10) at the same pace both before and after the detection point (distinguishing and classifying memory cells into the different subsets of memory cells based on programming). So for example, if the system uses a step size of 0.2 volts, then the programming signal Vpgm is stepping at 0.2V before detection, then after detection Vpgm splits into two pulses with the lower magnitude programming pulse (which is applied to fast programming memory cells) still stepping up by 0.2V from before and after detection. This way the fast programming memory cells continue to move at the same pace both before and after detection.

In the embodiments which change programming speed by a combination of adjusting the magnitude of the programming pulse applied to the word line and adjusting the voltage applied to the bit line, right at the detection point the system applies a Vb1 bias (ie Vsp1) on very fast programming memory cells. This means that the very fast programming memory cells will suddenly experience a slow down right after compaction starts, which may cause some loss of performance. Therefore, in one alternative embodiment, at the programming pulse right after the detection point, instead of using the same step size (DVpgm volts) for Vpgm, the system can use a larger step size DVpgm+K volts. By tuning the K, the system can make sure that the very fast programming memory cells maintain their program speed as it is, and the change only influences program speed of the fast programming memory cells. Similarly for slow programming memory cells, they change in magnitude of the programing pulse at the programming pulse right after the detection point should also use the larger step size DVpgm+K volts, where K is tunable to make sure that the slow programming memory cells maintain their program speed. In short, just for the special case of the programming pulse immediately after detection point, the system adds K volts to the DVpgm. On subsequent programming pulses, the system reverts back to using the standard DVpgm used prior to the detection.

The above described technology describes a means for narrowing the threshold voltage distributions.

One embodiment includes an apparatus, comprising non-volatile memory cells and a control circuit in communication with the memory cells. The control circuit is configured to apply different programming signals to different subsets of the memory cells being programmed to a common programmed state.

In one example embodiment, the control circuit is configured to apply different programming signals to different subsets of the memory cells by providing programming signals with different magnitudes at different times to different subsets of the memory cells being programmed to the common programmed state during a common iteration of a programming process.

In one example embodiment, the control circuit is configured to apply different programming signals to different subsets of the memory cells by providing programming signals with different magnitudes to different subsets of the memory cells being programmed to the common programmed state during a common programming process.

In one example implementation, the control circuit configured to distinguish between fast programming memory cells and slow programming memory cells, the fast programming memory cells comprise a first subset of the memory cells, the slow programming memory cells comprise a second subset of the memory cells; the control circuit configured to apply different programming signals to subsets of the memory cells by providing a first set of programming pulses to the fast programming memory cells and a second set of programming pulses to the slow programming memory cells, the second set of programming pulses have a higher magnitude than corresponding programming pulses in the first set of programming pulses; the control circuit configured to additionally provide different bit line voltages to the different subsets of the memory cells being programmed to a common programmed state; the control circuit configured to use a first step size between programming pulses of the first set of programming pulses and between programming pulses of the second set of programming pulses except for programming pulses immediately after distinguishing between fast programming memory cells and slow programming memory cells; the control circuit configured to use a second step size between programming pulses of the first set of programming pulses and between programming pulses of the second set of programming pulses immediately after distinguishing between fast programming memory cells and slow programming memory cells; and the second step size is larger than the first step size by a tunable difference.

One embodiment includes an apparatus, comprising: non-volatile memory cells; a classifying circuit connected to the memory cells, the classifying circuit configured to classify the memory cells into a plurality of groups based on programming performance; a programming and compaction circuit connected to the non-volatile memory cells, the programming circuit configured to provide programming signals to the non-volatile memory cells; and a selection circuit connected to the programming and compaction circuit, the selection circuit selectively directs the programming circuit to provide separate programming signals to the plurality of groups while programming the plurality of groups to a common data state during a programming process.

One embodiment includes an apparatus, comprising: a memory interface for communicating with non-volatile memory cells and a control circuit in communication with the memory cells. The control circuit configured to program the memory cells to one or more of programmed states by causing an attribute value for the memory cells to change. The control circuit configured to cause fast programming memory cells to be distinguished from slow programming memory cells. Based on the distinguishing between fast programming memory cells and slow programming memory cells, the control circuit causes a first programming signal to be applied to slow programming memory cells and a second programming signal to be applied to fast programming memory cells. The first programming signal is higher in magnitude than the second programming signal during a common iteration of a programming process.

One embodiment includes a method, comprising: programming memory cells to one or more of a plurality of programmed states by changing an attribute value for the memory cells; distinguishing between fast programming memory cells and slow programming memory cells; and based on the distinguishing between fast programming memory cells and slow programming memory cells, applying a first programming signal to slow programming memory cells and applying a second programming signal to fast programming memory cells, the first programming signal is higher in magnitude than the second programming signal during a common programming iteration.

For purposes of this document, it should be noted that the dimensions of the various features depicted in the figures may not necessarily be drawn to scale.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more others parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus, comprising:
non-volatile memory cells; and
a control circuit in communication with the memory cells, the control circuit configured to apply different programming signals to subsets of the memory cells being programmed to a common programmed state.

2. The apparatus of claim 1, wherein:
the control circuit configured distinguish and classify the memory cells into the different subsets of memory cells based on speed of programming.

3. The apparatus of claim 1, wherein:
the control circuit configured to apply different programming signals to subsets of the memory cells by providing different voltage magnitudes to the subsets of the memory cells being programmed to the common programmed state.

4. The apparatus of claim 1, wherein:
the control circuit configured to apply different programming signals to different subsets of the memory cells by providing programming signals at different times to the different subsets of the memory cells being programmed to the common programmed state.

5. The apparatus of claim 1, wherein:
the control circuit configured to distinguish between fast programming memory cells and slow programming memory cells, the fast programming memory cells comprise a first subset of the memory cells, the slow programming memory cells comprise a second subset of the memory cells.

6. The apparatus of claim 5, wherein:
the control circuit configured to apply different programming signals to subsets of the memory cells by providing a first set of programming pulses to the fast programming memory cells and a second set of programming pulses to the slow programming memory cells, the second set of programming pulses have a higher magnitude than corresponding programming pulses in the first set of programming pulses.

7. The apparatus of claim 6, wherein:
the control circuit configured to additionally provide different bit line voltages to the different subsets of the memory cells being programmed to a common programmed state.

8. The apparatus of claim 7, wherein:
the control circuit configured to use a first step size between programming pulses of the first set of programming pulses and between programming pulses of the second set of programming pulses except for programming pulses immediately after distinguishing between fast programming memory cells and slow programming memory cells;
the control circuit configured to use a second step size between programming pulses of the first set of programming pulses and between programming pulses of the second set of programming pulses immediately after distinguishing between fast programming memory cells and slow programming memory cells; and
the second step size is larger than the first step size by a tunable difference.

9. The apparatus of claim 5, wherein:
the control circuit configured to distinguish between fast programming memory cells and slow programming memory cells by sensing whether total measured current through the memory cells is half of total potential current and identifying memory cells that turn on as slow programming memory cells when the total measured current through the memory cells is half of total potential current.

10. The apparatus of claim 1, wherein:
the non-volatile memory cells are arranged in a three dimensional structure.

11. An apparatus, comprising:
non-volatile memory cells;
a classifying circuit connected to the memory cells, the classifying circuit configured to classify the memory cells into a plurality of groups based on programming performance;
a programming and compaction circuit connected to the non-volatile memory cells, the programming circuit configured to provide programming signals to the non-volatile memory cells; and
a selection circuit connected to the programming and compaction circuit, the selection circuit selectively directs the programming circuit to provide separate programming signals to the plurality of groups while programming the plurality of groups to a common data state during a programming process.

12. The apparatus of claim 11, wherein:
the classifying circuit configured to classify the memory cells as faster programming memory cells and slower programming memory cells, the plurality of groups include a group of faster programming memory cells and a group of slower programming memory cells.

13. The apparatus of claim 11, wherein:
the classifying circuit configured to classify the memory cells as faster programming memory cells and slower programming memory cells based on relative position of threshold voltage in a natural threshold voltage distribution, with faster programming memory cells having higher threshold voltages and slower programming memory cells having lower threshold voltages.

14. The apparatus of claim 13, wherein:
the programming and compaction circuit configured to separately provide programming to the plurality of groups by providing different programming pulses to the slower programming memory cells than to the faster programming memory cells.

15. The apparatus of claim 13, wherein:
the programming and compaction circuit configured to separately provide programming to the plurality of groups by applying programming voltages to the slower programming memory cells that are higher in magnitude than the programming voltages applied to the faster programming memory cells during a common iteration of a programming process by a magnitude is a function of a natural threshold voltage distribution.

16. The apparatus of claim 11, further comprising:
a plurality of latches, the classifying circuit stores results of classifying the memory cells in the latches, the programming and compaction circuit configured to use the results stored in the latches multiple times during a common programming process.

17. An apparatus, comprising:
a memory interface for communicating with non-volatile memory cells; and
a control circuit in communication with the memory cells, the control circuit configured to program the memory cells to one or more of programmed states by causing an attribute value for the memory cells to change, the control circuit configured to cause fast programming memory cells to be distinguished from slow programming memory cells, based on the distinguishing between fast programming memory cells and slow programming memory cells the control circuit causes a first programming signal to be applied to slow programming memory cells and a second programming signal to be applied to fast programming memory cells, the first programming signal is higher in magnitude than the second programming signal during a common iteration of a programming process.

18. The apparatus of claim 17, wherein:
the first programming signal includes a first set of voltage pulses, the second programming signal includes a second set of programming pulses, both the first set of voltage pulses and the second set of voltage pulses are driven on a common word line connected to the fast programming memory cells and slow programming memory cells, the control circuit configured to cause the fast programming memory cells to be inhibited when the first set of voltage pulses are driven on the common word line, the control circuit configured to cause the slow programming memory cells to be inhibited when the second set of voltage pulses are driven on the common word line.

19. The apparatus of claim 18, wherein:
the first set of voltage pulses are higher in magnitude than corresponding voltage pulses of the second set of voltage pulses; and
the non-volatile memory cells are arranged in a three dimensional structure.

20. The apparatus of claim 18, wherein:
the control circuit configured to cause a first bit line voltage to be applied to slow programming memory cells and a second bit line voltage to be applied to fast programming memory cells, the second bit line voltage is higher in magnitude than the first bit line voltage.
